(19) United States
(12) Patent Application Publication
(10) Pub. No.: US 2020/0203242 A1
(43) Pub. Date: Jun. 25, 2020

(54) LOW COST RELIABLE FAN-OUT FAN-IN CHIP SCALE PACKAGE

(71) Applicant: Texas Instruments Incorporated, Dallas, TX (US)

(72) Inventor: Sreenivasan K. Koduri, Allen, TX (US)

(73) Assignee: Texas Instruments Incorporated, Dallas, TX (US)

(21) Appl. No.: 16/225,135

(22) Filed: Dec. 19, 2018

(51) Int. Cl. H01L 23/31; H01L 25/065; H01L 23/00; H01L 21/56

(52) U.S. Cl. CPC H01L 23/3114; H01L 25/0655; H01L 24/09; H01L 24/17; H01L 24/29; H01L 2224/12105; H01L 24/73; H01L 21/56; H01L 2224/17104; H01L 2224/04105; H01L 24/49

(57) ABSTRACT

A microelectronic device, in a fan-out fan-in chip scale package, has a die and an encapsulation material at least partially surrounding the die. Fan-out connections from the die extend through the encapsulation material and terminate adjacent to the die. The fan-out connections include wire bonds, and are free of photolithographically-defined structures. Fan-in/out traces connect the fan-out connections to bump bond pads. The die and at least a portion of the bump bond pads partially overlap each other. The microelectronic device is formed by mounting the die on a carrier, and forming the fan-out connections, including the wire bonds, without using a photolithographic process. The die and the fan-out connections are covered with an encapsulation material, and the carrier is subsequently removed, exposing the fan-out connections. The fan-in/out traces are formed so as to connect to the exposed portions of the fan-out connections, and extend to the bump bond pads.

### FIELD

This disclosure relates to the field of microelectronic devices. More particularly, this disclosure relates to chip scale packaging of microelectronic devices.

### BACKGROUND

Chip scale packaging of microelectronic devices provides low cost and small area. As chip sizes continue to shrink, accommodating bump bonds for all the terminals of the chip becomes challenging. Expanding the packages with lead frames undesirably adds costs to the packages.

### SUMMARY

The present disclosure introduces a microelectronic device having a fan-out fan-in chip scale package, and a method for forming the microelectronic device. The microelectronic device includes a die and an encapsulation material at least partially surrounding the die. Fan-out connections extend from the die through the encapsulation material and terminate adjacent to the die. The fan-out connections include wire bonds from the die. The fan-out connections are free of photolithographically-defined structures. Fan-in/out traces contact the fan-out connections adjacent to the die. The fan-in/out traces include bump bond pads. At least a portion of the bump bond pads are located at least partially under the die.

The microelectronic device is formed by mounting the die on a carrier, and forming the fan-out connections, including the wire bonds, without using a photolithographic process. The die and the fan-out connections are covered with an encapsulation material, and the carrier is subsequently removed, exposing the fan-out connections. The fan-in/out traces are formed so as to connect to the exposed portions of the fan-out connections, and extend at least partway under the die.

### BRIEF DESCRIPTION OF THE VIEWS OF THE DRAWINGS

FIG. 1A through FIG. 1J include various views of a microelectronic device having a fan-out fan-in chip scale package, depicted in stages of an example method of formation.

FIG. 2A through FIG. 2L include various views of a microelectronic device having a fan-out fan-in chip scale package, depicted in stages of another example method of formation.

FIG. 3A through FIG. 3O include various views of a microelectronic device having a fan-out fan-in chip scale package, depicted in stages of a further example method of formation.

FIG. 4A through FIG. 4M include various views of a microelectronic device having a fan-out fan-in chip scale package, depicted in stages of a further example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

This application is related to the following U.S. patent applications: U.S. patent application Ser. No. 12/______, Attorney Docket Number TI-78741, filed concurrently with this application, U.S. patent application Ser. No. 12/______, Attorney Docket Number TI-78743, filed concurrently with this application, and U.S. patent application Ser. No. 12/______, Attorney Docket Number TI-78745, filed concurrently with this application. For applications filed concurrently with this application, with their mention in this section, these patent applications are not admitted to be prior art with respect to the present invention.

A microelectronic device has a die in a fan-out fan-in chip scale package. The fan-out fan-in chip scale package includes fan-out connections extending from the die. The fan-out connections include wire bonds connected to the die. The fan-out connections are free of photolithographically-defined structures. An encapsulation material at least partially surrounds the die and the wire bonds. Fan-in/out traces connect to the fan-out connections at locations adjacent to the die. The fan-in/out traces include bump bond pads which extend at least partially under the die. Bump bond pads are electrically conductive pads for external connections to the microelectronic device using an electrically conductive connection material. Bump bond pads are distinguished from leads which extend from microelectronic devices having leads. The fan-in/out traces are located outside of the encapsulation material. An electrically conductive connection material, such as a solder or an electrically conductive adhesive, may be disposed on the bump bond pads. For the purposes of this disclosure, a fan-out fan-in chip scale package has at least one fan-in/out trace, referred to as a fan-in trace, which extends partway under the die, and includes at least one fan-in/out trace, referred to as a fan-out trace, which does not extend partway under the die, in which the fan-out connections are formed after the die is singulated from a wafer which contained the die.

The microelectronic device is formed by mounting the die on a carrier, and forming the fan-out connections, including the wire bonds, without using a photolithographic process. The die and the fan-out connections are covered with an encapsulation material, and the carrier is subsequently removed, exposing the fan-out connections. The fan-in/out traces are formed so as to connect to the exposed portions of the fan-out connections, and extend at least partway under the die. The fan-in/out traces include bump bond pads which are located at least partway under the die. An electrically conductive connection material may be formed on the bump bond pads. The electrically conductive connection material may include, for example, a solder or an electrically conductive adhesive.

For the purposes of this disclosure, photolithographically-defined structures include structures which are formed by forming a layer, using a photolithographic process to form an etch mask over the layer, and removing the layer where exposed by the etch mask. Photolithographically-defined structures include structures which are formed by using a photolithographic process to form a plating mask, and plating metal in areas exposed by the plating mask. For the purposes of this disclosure, photolithographic processes include exposing photosensitive material to patterned radiation using a photomask, exposing photosensitive material to patterned radiation using a maskless light source such as a micro-mirror system, X-ray lithography, e-beam lithography, and exposing photosensitive material to patterned radiation using scanned laser lithography.

For the purposes of this disclosure, the term “wire bonding” is understood to encompass bonding with round bond wire and with ribbon wire. Furthermore, the term “wire bonding” is understood to encompass ball bonding, stitch bonding, and wedge bonding. Similarly, the term “wire bond” is understood to encompass bonds with round bond wire and ribbon wire, and encompass bonds with ball bonds, stitch bonds, and wedge bonds. The term “die” is used in this disclosure to denote a single chip or more than one chip.

It is noted that terms such as top, bottom, over, above, and under may be used in this disclosure. These terms should not be construed as limiting the position or orientation of a structure or element, but should be used to provide spatial relationship between structures or elements.

The terms “parallel” and “perpendicular” are used to describe spatial relationships of elements with respect to other elements. In one aspect of this disclosure, the terms “parallel” and “perpendicular” encompass spatial relationships that are parallel or perpendicular within fabrication tolerances encountered in the fabrication of the respective elements. In another aspect, the terms “parallel” and “perpendicular” encompass spatial relationships that are parallel or perpendicular within measurement tolerances encountered when measuring the spatial relationships.

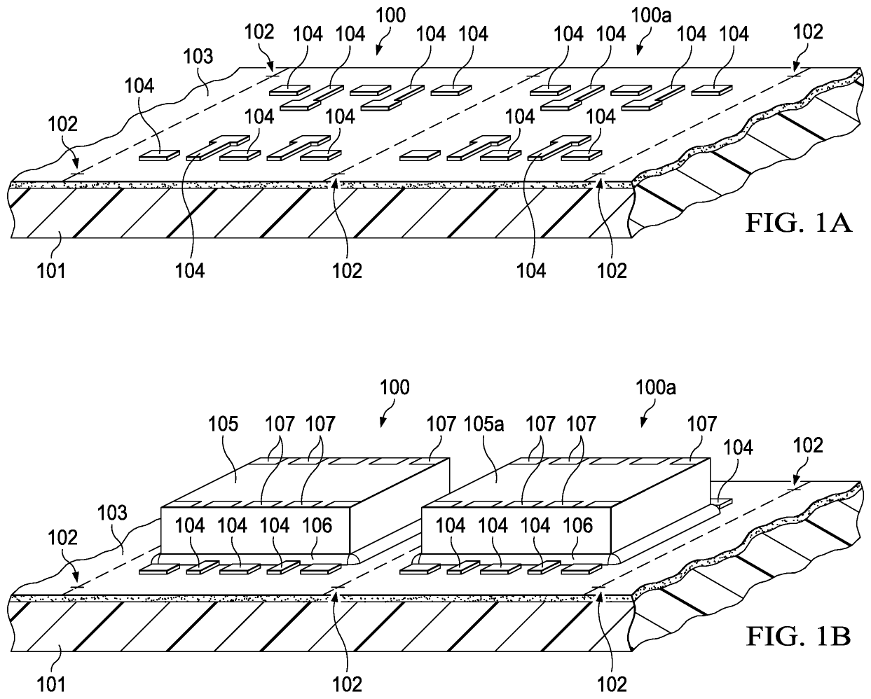

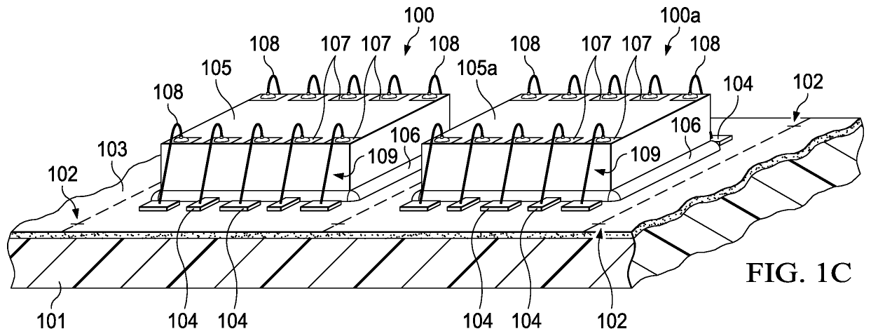

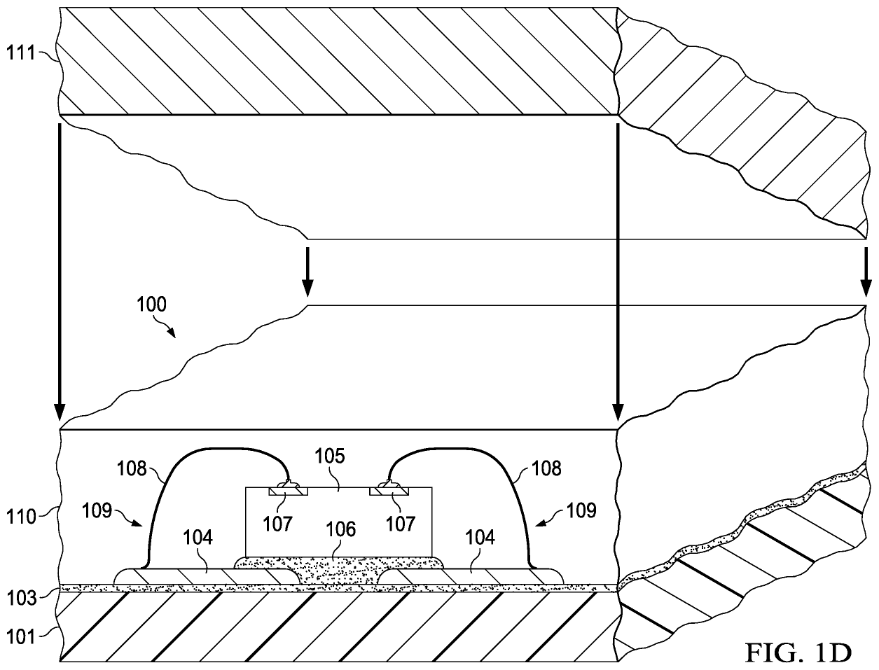

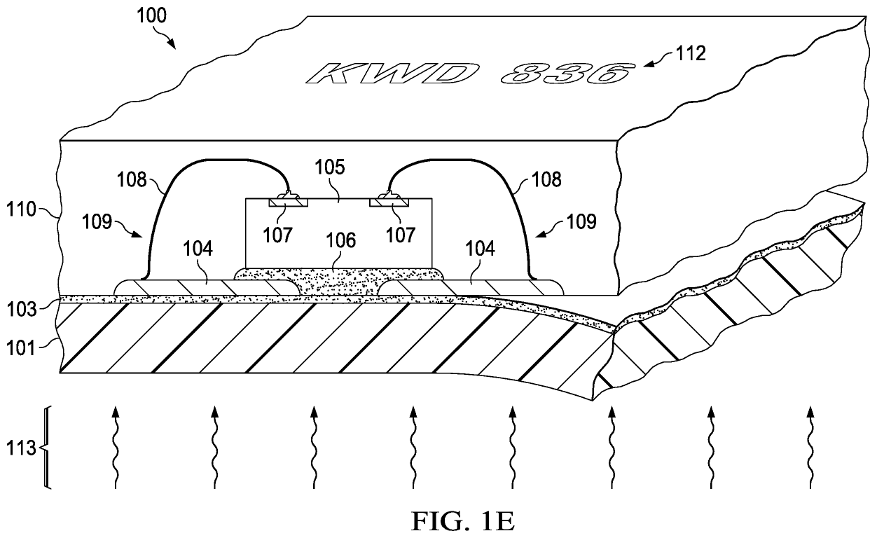

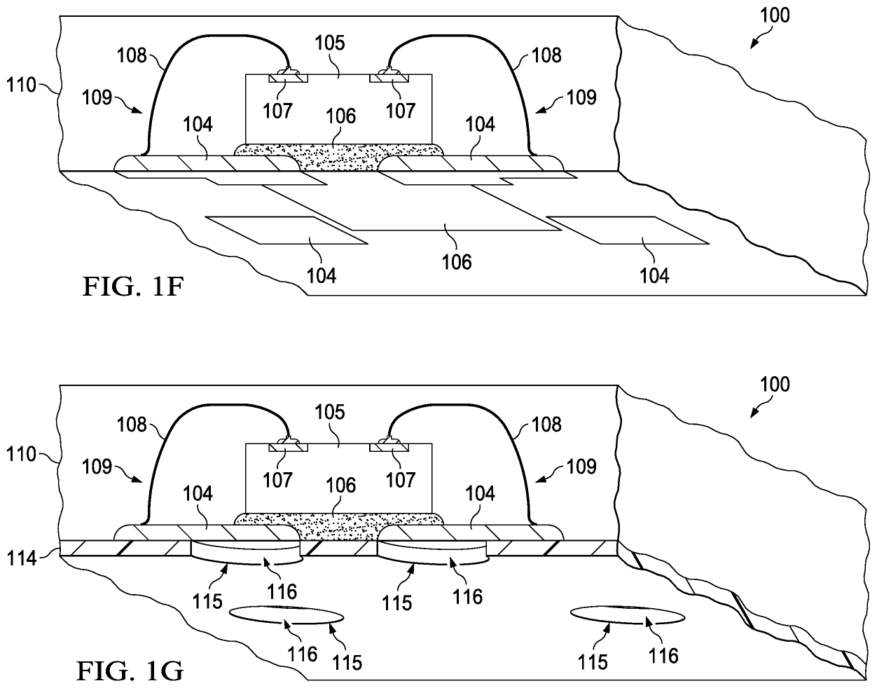

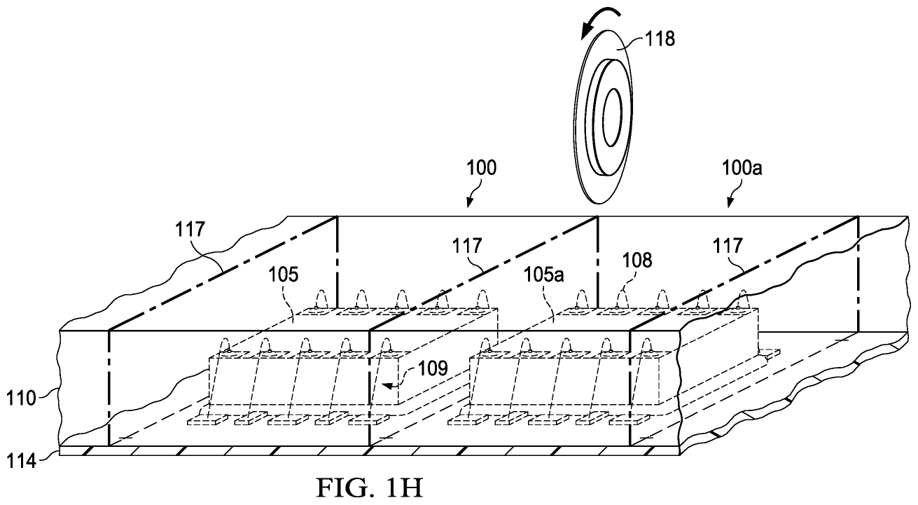

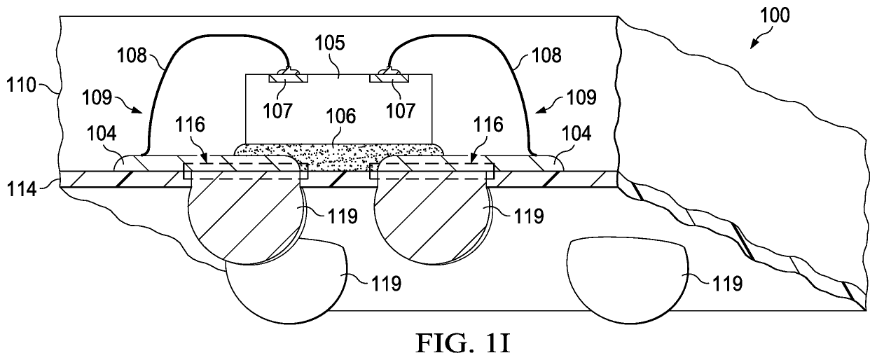

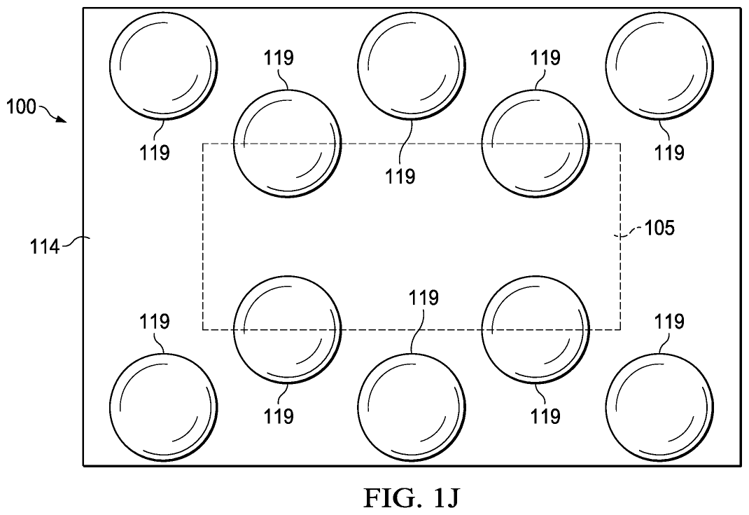

FIG. 1A through FIG. 1J include various views of a microelectronic device having a fan-out fan-in chip scale package, depicted in stages of an example method of formation. Referring to FIG. 1A, formation of the microelectronic device 100 begins by providing a carrier 101. The carrier 101 includes an area for the microelectronic device 100, and may include areas for additional microelectronic devices 100a. The carrier 101 includes one or more materials suitable as a substrate for forming wire bonds, and further suitable for separation from an encapsulation material, such as epoxy. In this example, the carrier 101 may be flexible, to facilitate separation from the encapsulation material. The carrier 101 may include, for example, polycarbonate, phenolic, or acrylic material. The carrier 101 may also include particles of a hard inorganic material, such as aluminum oxide or diamond, to provide increased hardness, to enhance formation of the wire bonds. The carrier 101 may have a laminated structure, with a thin, hard surface layer of glass or metal, attached to a flexible substrate. Other compositions and structures for the carrier 101 are within the scope of this example. The carrier 101 may have alignment marks 102 to assist subsequent placement of die on the carrier 101. The carrier 101 may have a continuous, belt-like configuration, or may have a flat rectangular configuration.

A releasable adhesive 103 is disposed on the carrier 101. The releasable adhesive 103 may include, for example, a photolabile which exhibits reduced adhesion after exposure to light in a prescribed wavelength band. The photolabile material may be implemented as an ultraviolet (UV) release material, which reduces adhesion of the releasable adhesive 103 upon exposure to UV light. In the case of the releasable adhesive 103 being implemented with a photolabile material, the carrier 101 is transmissive to light in an appropriate wavelength band. Other manifestations of the releasable adhesive 103, such as including a thermolabile material, which reduces adhesion of the releasable adhesive 103 upon being heated to a prescribed temperature, are within the scope of this example. Thermolabile materials are sometimes referred to as thermal release materials.

Fan-in/out traces 104 are disposed on the releasable adhesive 103 in the area for the microelectronic device 100, and in the areas for the additional microelectronic devices 100a. The fan-in/out traces 104 may be implemented as preformed metal pads, applied using a tape backing, which is subsequently removed. The fan-in/out traces 104 are electrically conductive, and have surfaces suitable for forming wire bonds. The fan-in/out traces 104 may include a barrier layer contacting the releasable adhesive 103, a base layer on the barrier layer, and a wire bondable layer on the base layer. The base layer may include, for example, 50 microns to 250 microns of copper or a copper alloy, which may advantageously provide low resistance for the fan-in/out traces 104 at low cost, compared to gold or silver. The barrier layer may include nickel, palladium, cobalt, titanium, or molybdenum, to reduce formation of intermetallic compounds between copper in the base layer and tin in subsequently formed solder bumps on the fan-in/out traces 104. The wire bondable layer may include, for example, gold or platinum, and may be 100 nanometers to 2 microns thick, to provide an oxidation-resistant surface for wire bonding. The fan-in/out traces 104 may include an adhesion layer of titanium or a titanium alloy between the base layer and the wire bondable layer, to improve adhesion of the wire bondable layer to the base layer and reduce diffusion of copper from the base layer into the wire bondable layer. In this example, the fan-in/out traces 104 are disposed on the releasable adhesive 103 without using a photolithographic process.

Referring to FIG. 1B, a die 105 is positioned on the releasable adhesive 103 in the area for the microelectronic device 100, partially overlapping a fan-in portion of the fan-in/out traces 104. The die 105 may be implemented as an integrated circuit, a discrete semiconductor component, an electro-optical device, a microelectrical mechanical systems (MEMS) device, or other microelectronic die. An additional die 105a is positioned on the releasable adhesive 103 in the area for the additional microelectronic device 100a. The die 105 and the additional die 105a may be attached to the releasable adhesive 103 by a die attach material 106. The die attach material 106 may be implemented as a non-conductive adhesive such as an epoxy.

The die 105 and the additional die 105a may have terminals 107 for electrical connections to components in the die 105 and the additional die 105a. The terminals 107 may be manifested as bond pads, or may be manifested as circuit nodes, such as transistor source and drain nodes. The terminals 107 may include materials suitable for wire bonding, such as aluminum, copper, gold, or platinum.

Referring to FIG. 1C, wire bonds 108 are formed by a wire bonding process to connect the die 105 to the fan-in/out traces 104. FIG. 1C depicts the wire bonds 108 as formed using round bond wire. Other types of bond wire, such as ribbon bond wire, are within the scope of this example. The wire bonds 108 may include, for example, copper wire, gold wire, or aluminum wire. Copper wire in the wire bonds 108 may optionally have a coating of palladium or nickel to reduce corrosion or oxidation of the copper wire. The wire bonds 108 may be formed with ball bonds on the terminals 107 and stitch bonds on the fan-in/out traces 104, as depicted in FIG. 1C. Alternatively, the wire bonds 108 may be formed with stitch bonds on the terminals 107 and ball bonds on the fan-in/out traces 104. In this example, the wire bonds 108 provide fan-out connections 109 which connect the die 105 to the fan-in/out traces 104. The fan-out connections 109 are formed without using a photolithographic process, which may advantageously reduce a fabrication cost and a fabrication complexity of the microelectronic device 100.

Referring to FIG. 1D, an encapsulation material 110 is formed over the die 105, the fan-out connections 109, and the fan-in/out traces 104. The encapsulation material 110 contacts the die 105. The encapsulation material 110 may include epoxy or other material suitable for protecting the die 105 and the wire bonds 108 from moisture and contamination. The encapsulation material 110 may be formed by using a press mold 111; the press mold 111 is removed after the encapsulation material 110 is formed. Alternatively, the encapsulation material 110 may be formed by injection molding, by an additive process, or by other methods. The encapsulation material 110 extends to the releasable adhesive 103 adjacent to the die 105 and adjacent to the fan-in/out traces 104.

Referring to FIG. 1E, a device identification mark 112 may be formed on the encapsulation material 110. Alternatively, the device identification mark 112 may be formed at a subsequent step of the formation process.

The carrier 101 and the releasable adhesive 103 are removed from the microelectronic device 100 by separating the releasable adhesive 103 from the encapsulation material 110 and from the fan-in/out traces 104. In the case of the releasable adhesive 103 being implemented with a photolabile material, removal of the carrier 101 and the releasable adhesive 103 may be performed in this example using UV light 113 applied through the carrier 101, as indicated in FIG. 1E. In the case of the releasable adhesive 103 being implemented with other materials, other methods for removing the carrier 101 and the releasable adhesive 103 may be used as appropriate. Removal of the releasable adhesive 103 exposes the fan-in/out traces 104.

FIG. 1F depicts the microelectronic device 100 after the carrier 101 and the releasable adhesive 103, of FIG. 1E, have been removed. A fan-in portion of the fan-in/out traces 104 extend partway under the die 105. A fan-out portion of the fan-in/out traces 104 may be located adjacent to, but not extending partway under, the die 105.

Referring to FIG. 1G, a solder mask 114 is formed on the encapsulation material 110 and the fan-in/out traces 104, with solder bump apertures 115 which expose areas of the fan-in/out traces 104 for bump bond pads 116. The solder mask 114 may include a polymer material, such as epoxy or lacquer. The solder mask 114 may be formed, for example, by a screen printing process, an additive process such as a material jetting process or a material extrusion process, or a tape transfer process. Of the fan-in/out traces 104 which extend partway under the die 105, the bump bond pads 116 in these fan-in/out traces 104 are located at least partially under the die 105.

Referring to FIG. 1H, the microelectronic device 100 is singulated from the additional microelectronic devices 100a by cutting through the encapsulation material 110 in singulation lanes 117 between the microelectronic device 100 and the additional microelectronic devices 100a. The microelectronic device 100 may be singulated by a saw process using a saw blade 118, as indicated in FIG. 1H. Singulating the microelectronic device 100 may be facilitated by the absence of metal in the singulation lanes 117.

Referring to FIG. 1I, an electrically conductive connection material 119 is formed on the bump bond pads 116. The electrically conductive connection material 119 may be implemented as solder bumps 119, which may include, for example, tin and silver. The solder bumps 119 may also include other metals, such as copper, bismuth, or indium. One method of forming the solder bumps 119 may include placing preformed solder balls onto the bump bond pads 116, followed by a solder reflow process to improve contact between the solder and the fan-in/out traces 104. Another method of forming the solder bumps 119 may include disposing solder paste onto the bump bond pads 116, followed by a solder reflow process to remove volatile material from the solder paste and melt the solder onto the fan-in/out traces 104. A further method of forming the solder bumps 119 may include providing melted solder on the bump bond pads 116 using a solder bath or a solder fountain. Other methods of forming the solder bumps 119 are within the scope of this example.

FIG. 1J is a bottom view of the microelectronic device 100. A fan-in portion of the solder bumps 119 overlap at least partway over the die 105. A fan-out portion of the solder bumps 119 may be located adjacent to the die 105 without overlapping partway over the die 105. Having the solder bumps 119 located both overlap at least partway over the die 105 and adjacent to the die 105 without overlapping partway over the die 105 may advantageously reduce an area of the microelectronic device 100 while maintaining isolation between the solder bumps 119.

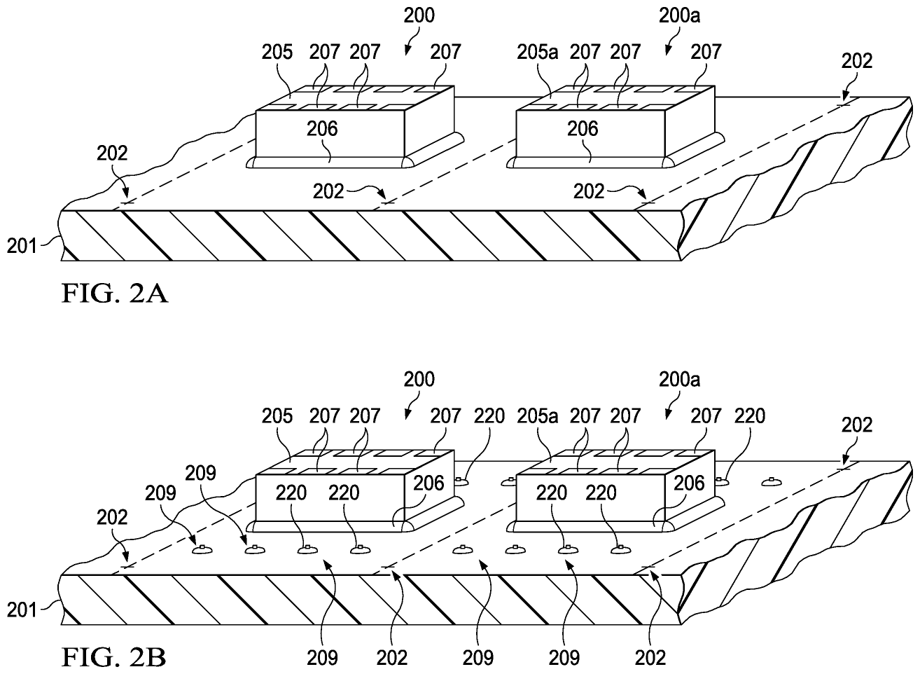

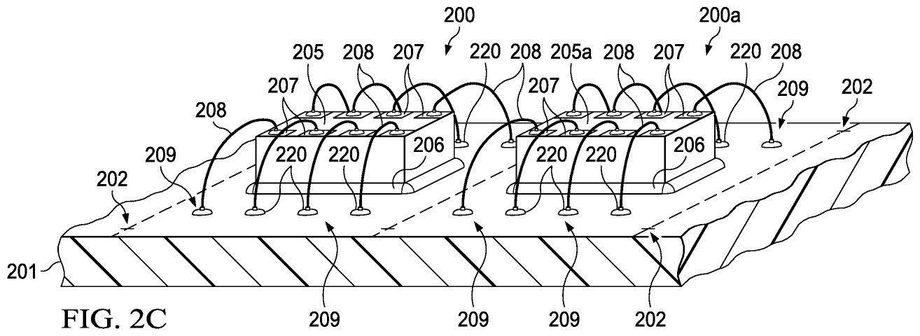

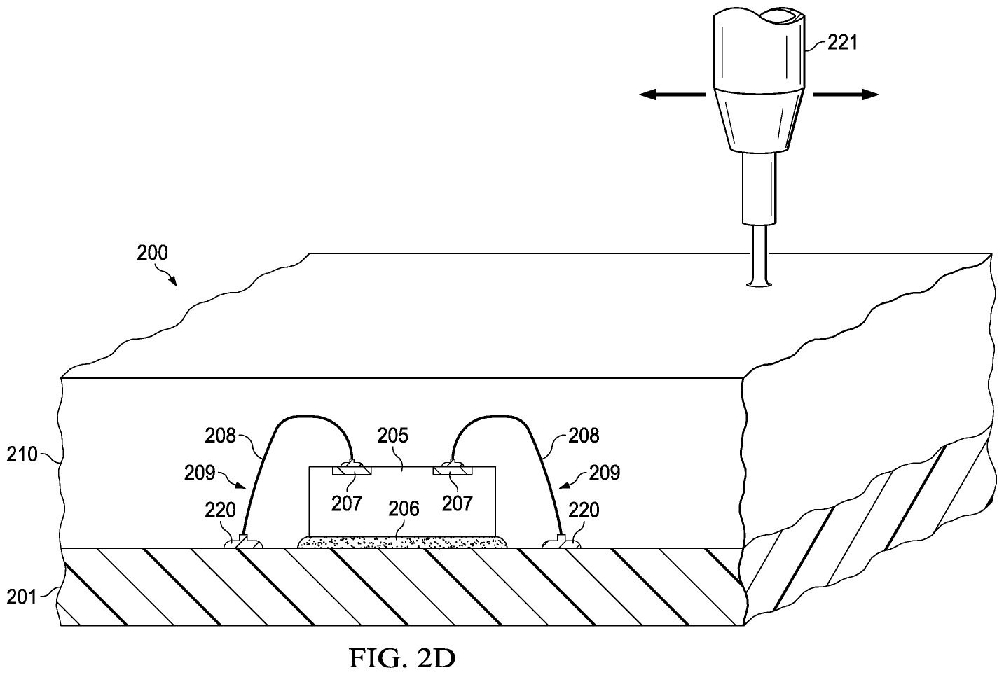

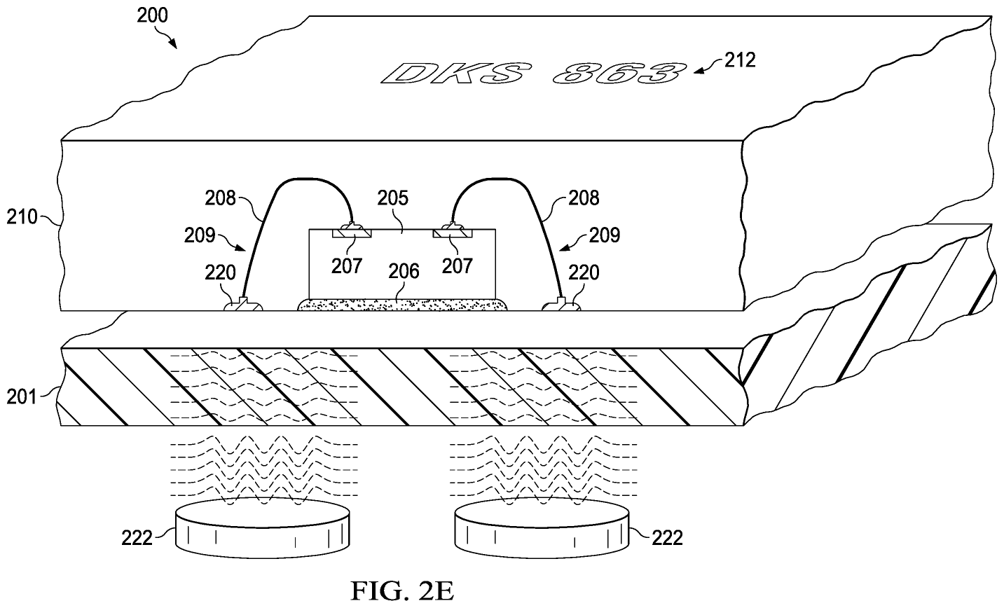

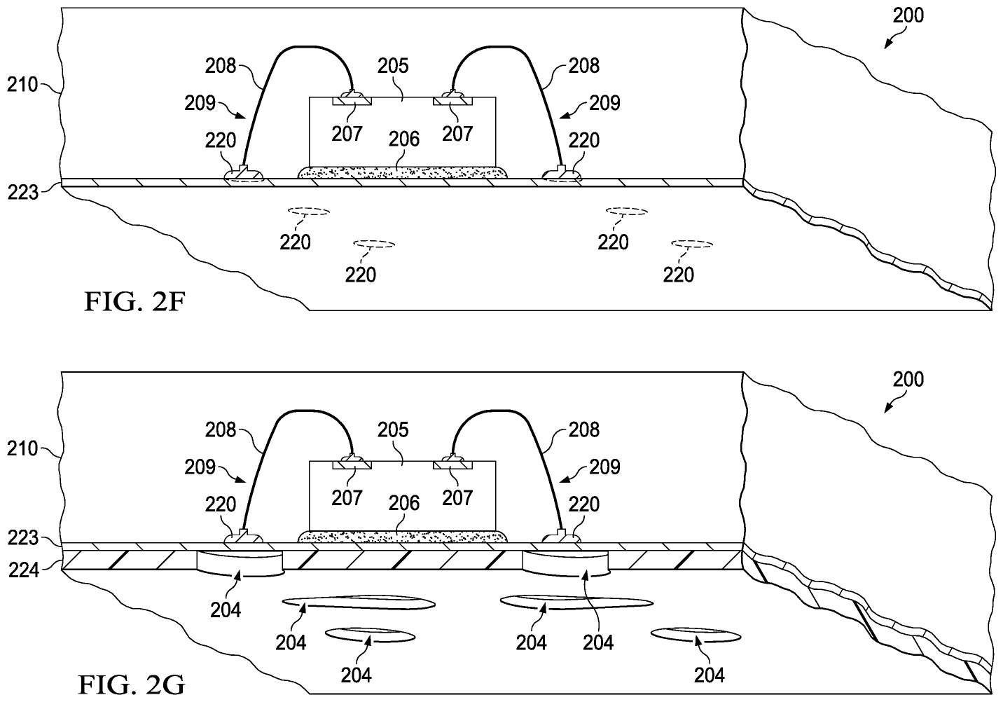

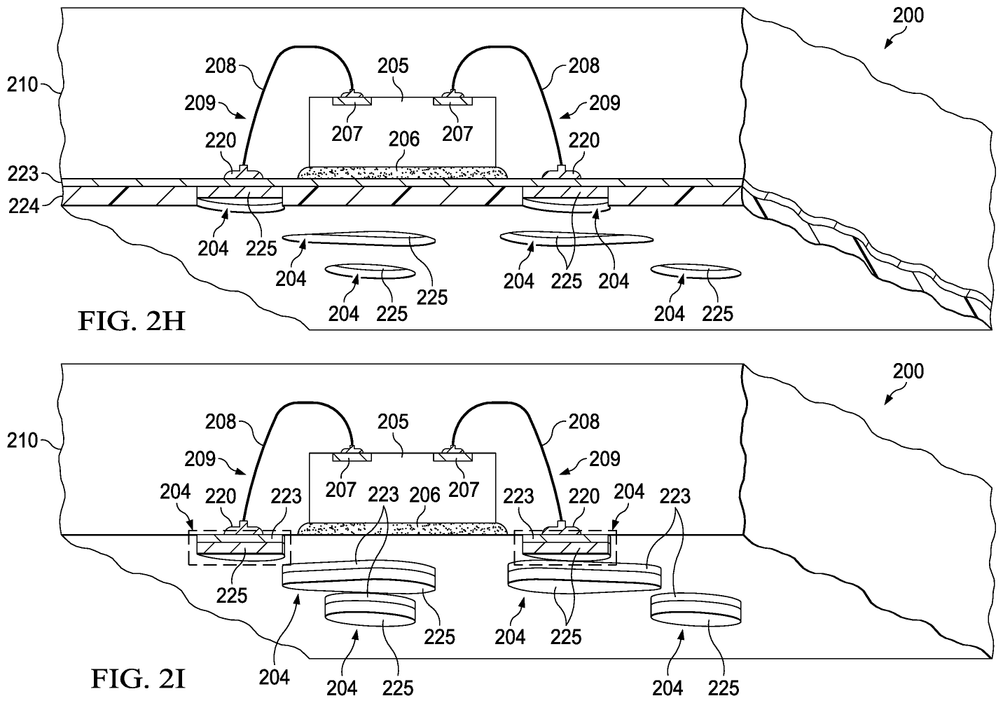

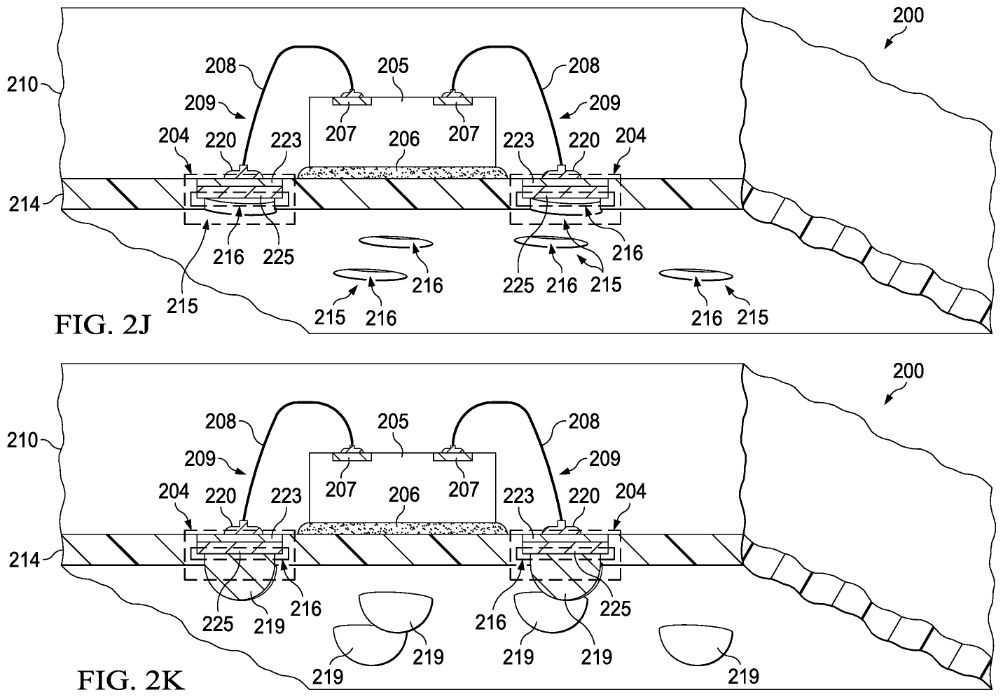

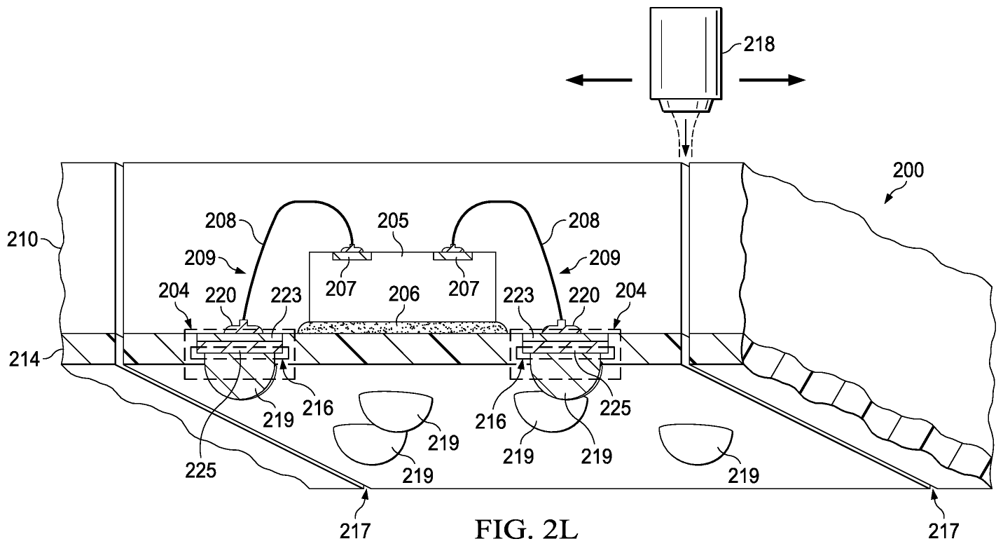

FIG. 2A through FIG. 2L include various views of a microelectronic device having a fan-out fan-in chip scale package, depicted in stages of another example method of formation. Referring to FIG. 2A, formation of the microelectronic device 200 begins by providing a carrier 201. The carrier 201 includes one or more materials suitable as a substrate for forming wire bond studs. In this example, the carrier 201 may be rigid, to facilitate formation of the wire bond studs. The carrier 201 may include, for example, glass, sapphire, silicon, metal, or ceramic. The carrier 201 may have a laminated structure, with a thin, hard surface layer, attached to a mechanically durable substrate. Other compositions and structures for the carrier 201 are within the scope of this example. The carrier 201 has an area for the microelectronic device 200, and an adjacent area for an additional microelectronic device 200a. The carrier 201 may have further areas for further microelectronic devices. The carrier 201 may have alignment marks 202 to assist subsequent placement of die on the carrier 201.

A die 205 is attached to the carrier 201 in the area for the microelectronic device 200, and an additional die 205a is attached to the carrier 201 in the area for the additional microelectronic device 200a. The die 205 and the additional die 205a may be manifested as integrated circuits, discrete semiconductor components, electro-optical devices, MEMS devices, or other microelectronic die. The die 205 and the additional die 205a may have terminals 207 suitable for wire bonding, providing electrical connections to components in the die 205 and the additional die 205a. The terminals 207 may be manifested as bond pads, or may be manifested as circuit nodes, such as transistor source and drain nodes. The die 205 and the additional die 205a may be substantially similar devices, or may be different devices. The die 205 and the additional die 205a may be attached to the carrier 201 by a die attach material 206, which may include epoxy or other adhesive.

Referring to FIG. 2B, wire bond studs 220 of fan-out connections 209 are formed on the carrier 201 using a wire bonding process, in the area for the microelectronic device 200, adjacent to the die 205, and in the area for the additional microelectronic device 200a, adjacent to the additional die 205a. The wire bond studs 220 may be formed by pressing a free air ball of a bond wire onto the carrier 201 with a wire bonding capillary to form a stud, and subsequently severing the bond wire proximate to the stud. The wire bond studs 220 may include primarily copper or gold, and may have some nickel or palladium from a barrier layer around the bond wire.

Referring to FIG. 2C, wire bonds 208 of the fan-out connections 209 are formed by a wire bonding process to connect the die 205 and the additional die 205a to the wire bond studs 220. FIG. 2C depicts the wire bonds 208 as formed using round bond wire. Other types of bond wire, such as ribbon bond wire, are within the scope of this example. The wire bonds 208 may include, for example, copper wire, gold wire, or aluminum wire. Copper wire in the wire bonds 208 may optionally have a coating of palladium or nickel to reduce corrosion or oxidation of the copper wire. The wire bonds 208 may be formed with ball bonds on the terminals 207 and stitch bonds on the wire bond studs 220, as depicted in FIG. 2C. Alternatively, the wire bonds 208 may be formed with stitch bonds on the terminals 207 and ball bonds on the wire bond studs 220. In the instant example, a combination of the wire bond studs 220 and the wire bonds 208 provide the fan-out connections 209. The fan-out connections 209 are formed without using a photolithographic process, which may advantageously reduce a fabrication cost and a fabrication complexity of the microelectronic device 200.

The wire bonds 208 may connect each of the terminals 207 to a separate wire bond stud 220, as indicated in FIG. 2C. Alternatively, one of the wire bond studs 220 may be connected by the wire bonds 208 to two or more of the terminals 207. Similarly, one of the terminals 207 may be connected by the wire bonds 208 to two or more of the wire bond studs 220.

Referring to FIG. 2D, an encapsulation material 210 is formed over the die 205 and the fan-out connections 209. The encapsulation material 210 contacts the die 205. The encapsulation material 210 may include epoxy or other material suitable for protecting the die 205, the wire bonds 208, and the wire bond studs 220 from moisture and contamination. The encapsulation material 210 may be formed by an additive process using a material extrusion apparatus 221. Alternatively, the encapsulation material 210 may be formed by injection molding, by press molding, or by other methods. The encapsulation material 210 extends to the carrier 201 adjacent to the die 205 and adjacent to the wire bond studs 220.

Referring to FIG. 2E, a device identification mark 212 may be formed on the encapsulation material 210. Alternatively, the device identification mark 212 may be formed at a subsequent step of the formation process.

The carrier 201 is removed from the microelectronic device 200 by separating the carrier 201 from the encapsulation material 210 and from the wire bond studs 220. Removal of the carrier 201 may be facilitated using ultrasonic vibrations applied by an ultrasonic transducer 222, as indicated in FIG. 2E. Other methods for removing the carrier 201, such as using a thermal shock, using penetrating solvents, or mechanical cleaving, are within the scope of this example. Removal of the carrier 201 exposes the wire bond studs 220.

Referring to FIG. 2F, a plating seed layer 223 is formed on the encapsulation material 210, contacting the exposed wire bond studs 220. The plating seed layer 223 is electrically conductive, and includes metals or other electrically conductive material suitable for a plating process. The plating seed layer 223 may include, for example, copper or copper alloy, nickel, platinum, palladium, or gold. The plating seed layer 223 may be, for example, 500 nanometers to 10 microns thick, and may be formed by a sputter process, an evaporation process, or a metal plasma spray process.

Referring to FIG. 2G, a plating mask 224 is formed on the plating seed layer 223. The plating mask 224 exposes the plating seed layer 223 in areas for fan-in/out traces 204. The areas for the fan-in/out traces 204 overlap the wire bond studs 220. The plating mask 224 may include polymer material, for example, novolac resin, which may be removed by organic solvents. The plating mask 224 may be formed, for example, by a tape transfer process, or by an additive process, such as a material jetting process. The plating mask 224 may have a thickness of 5 microns to 100 microns, for example.

Referring to FIG. 2H, plated leads 225 of the fan-in/out traces 204 are formed by an electroplating process on the plating seed layer 223 where exposed by the plating mask 224. The plated leads 225 may include a base layer of copper that contacts the plating seed layer 223, and may include a barrier layer on the base layer. The base layer may include copper or a copper alloy, and may have a thickness of 5 microns to 100 microns. The barrier layer may include nickel, palladium, cobalt, titanium, or molybdenum, to reduce formation of intermetallic compounds between copper in the base layer and tin in subsequently formed solder bumps on the plated leads 225. At least a portion of the plated leads 225 extend partway under the die 205.

Referring to FIG. 2I, the plating mask 224 of FIG. 2H is removed. The plating mask 224 may be removed by a wet process using organic solvents, or by a dry process using oxygen radicals, such as atomic oxygen in a downstream asher, or ozone. Subsequently, the plating seed layer 223 is removed where exposed by the plated leads 225. The plating seed layer 223 may be removed by a wet etch process, such as an aqueous solution of copper etchant. Removal of the plating seed layer 223 leaves the plated leads 225 in place, and leaves the plating seed layer 223 in place under the plated leads 225. The plating seed layer 223 under the plated leads 225, combined with the plated leads 225, provides the fan-in/out traces 204. At least a portion of the fan-in/out traces 204 extend under the die 205.

Referring to FIG. 2J, a solder mask 214 is formed on the encapsulation material 210 and the fan-in/out traces 204. The solder mask 214 has solder bump apertures 215 which expose areas of the fan-in/out traces 204 for bump bond pads 216. The solder mask 214 may include a polymer material. The solder mask 214 may be formed, for example, by a screen printing process, an additive process, or a tape transfer process. A portion of the fan-in/out traces 204 extend partway under the die 205, the bump bond pads 216 in this portion of the fan-in/out traces 204 are located at least partially under the die 205.

Referring to FIG. 2K, an electrically conductive connection material 219 is formed on the bump bond pads 216. The electrically conductive connection material 219 may be implemented as solder bumps 219 which may include tin and other metals, such as silver, copper, bismuth, or indium, to provide a desired melting temperature, resistance, and reliability. The solder bumps 219 may be formed by placing preformed solder balls onto the bump bond pads 216, disposing solder paste onto the bump bond pads 216, or providing melted solder on the bump bond pads 216. Formation of the solder bumps 219 may include a solder reflow process to provide a desired composition of the solder bumps 219 and to improve contact between the solder bumps 219 and the bump bond pads 216.

Referring to FIG. 2L, the microelectronic device 200 is singulated by cutting through the encapsulation material 210 in singulation lanes 217 around a lateral perimeter of the microelectronic device 200. The microelectronic device 200 may be singulated by a laser ablation process using a laser 218, as indicated in FIG. 2L. Singulating the microelectronic device 200 may be facilitated by the absence of metal in the singulation lanes 217.

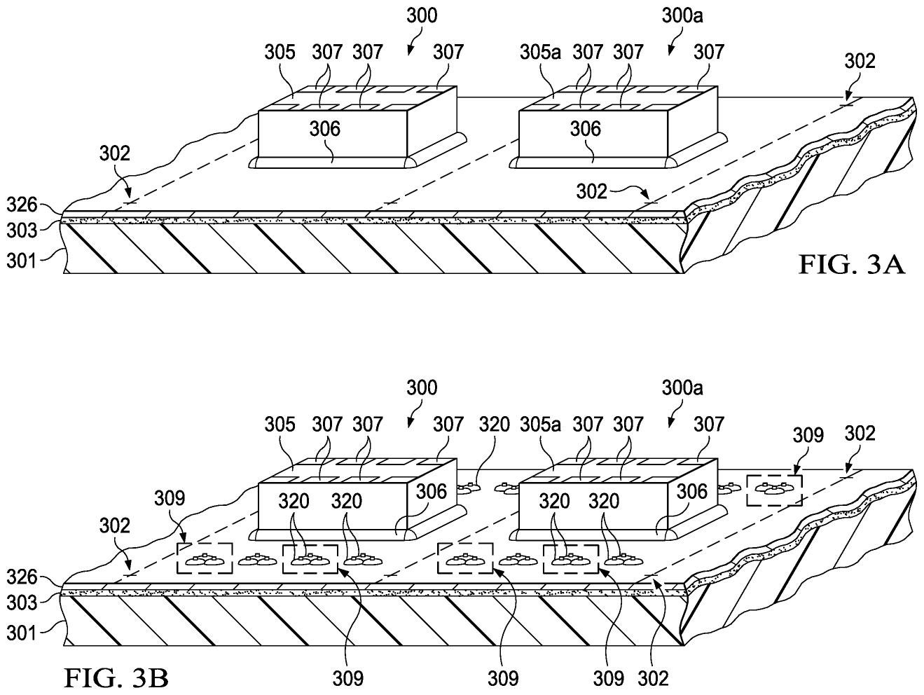

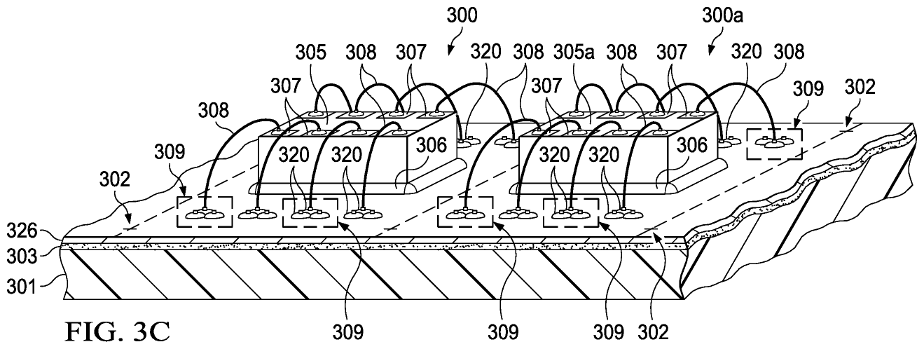

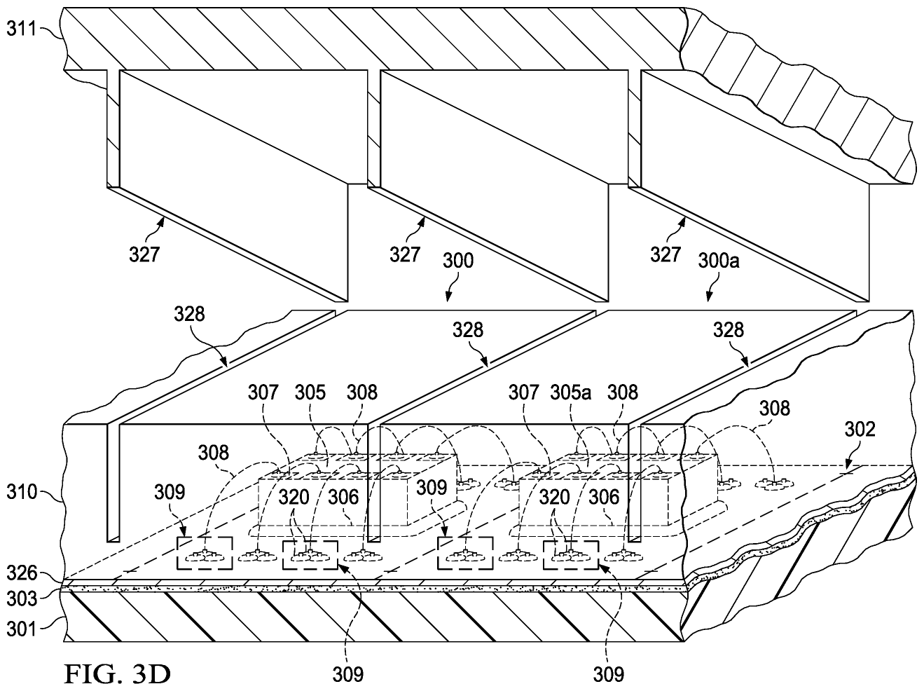

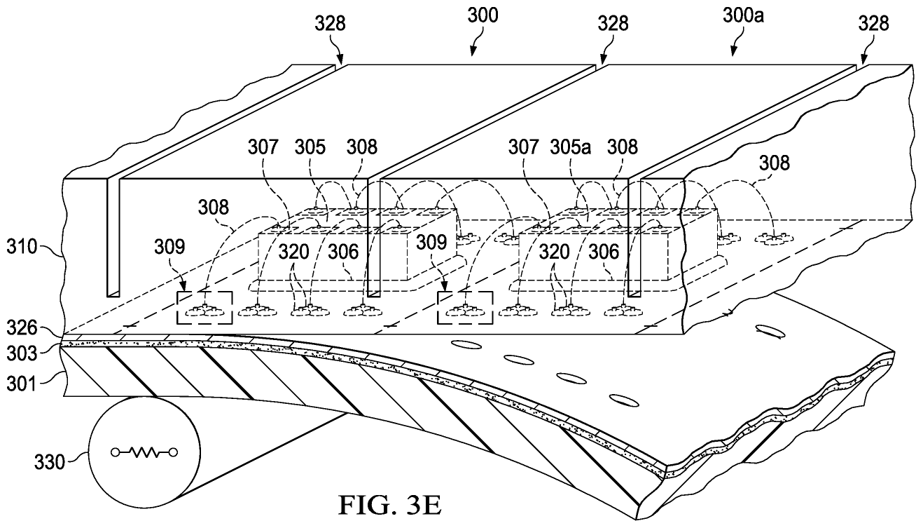

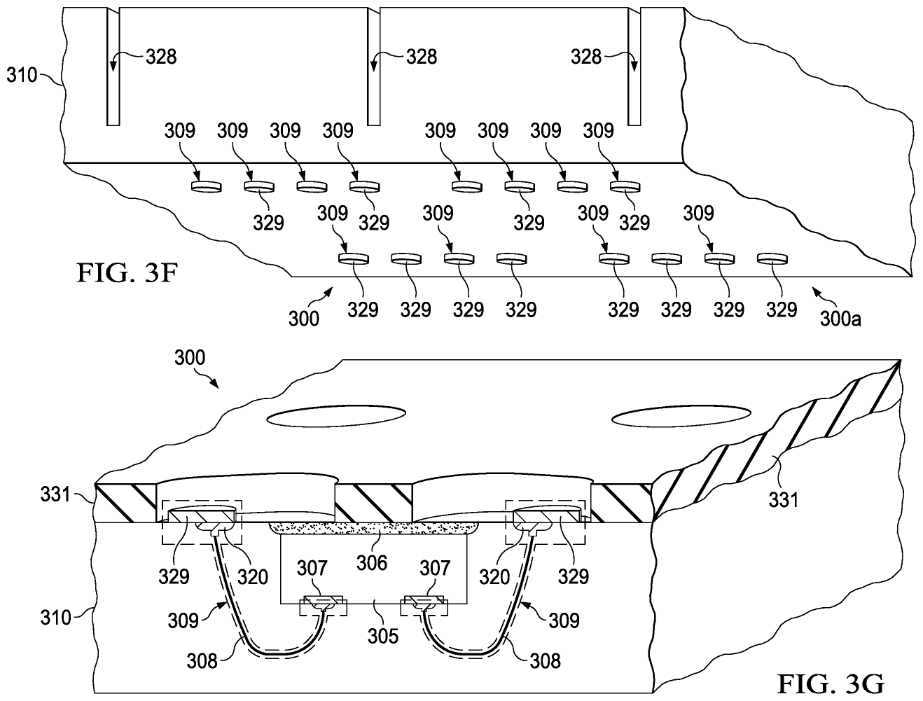

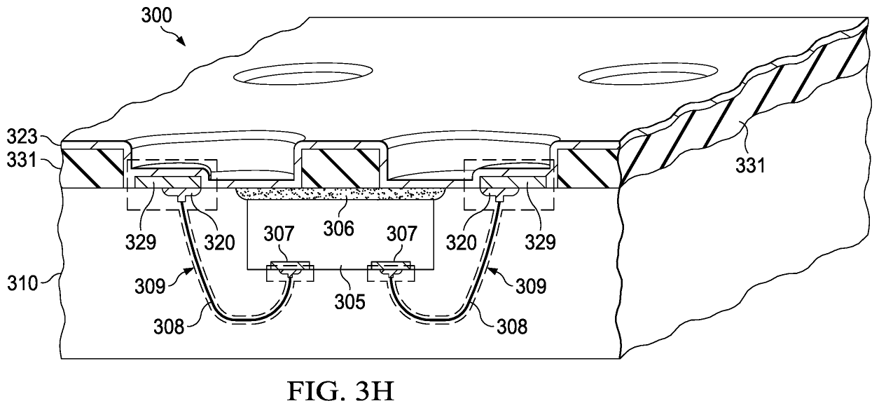

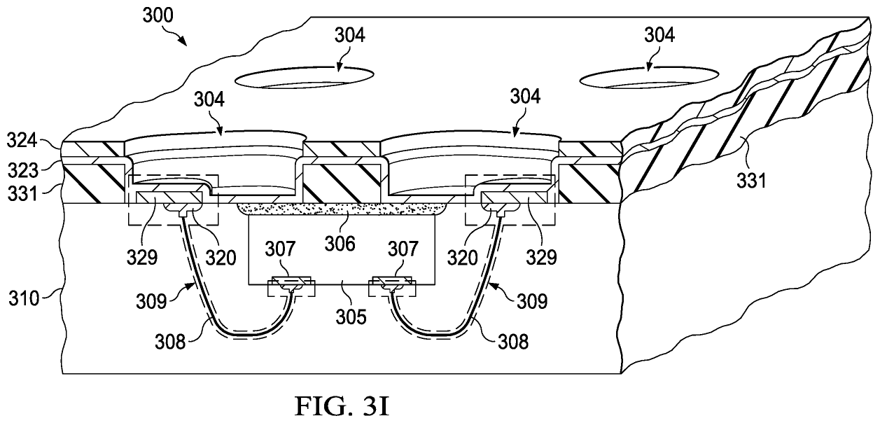

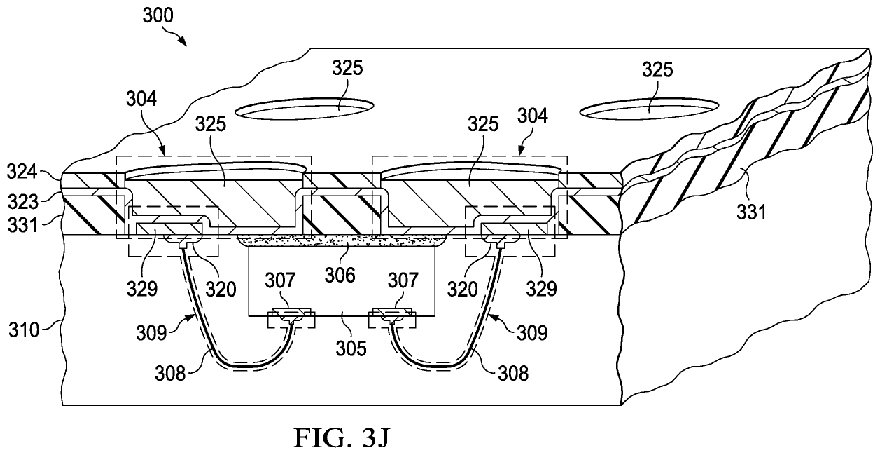

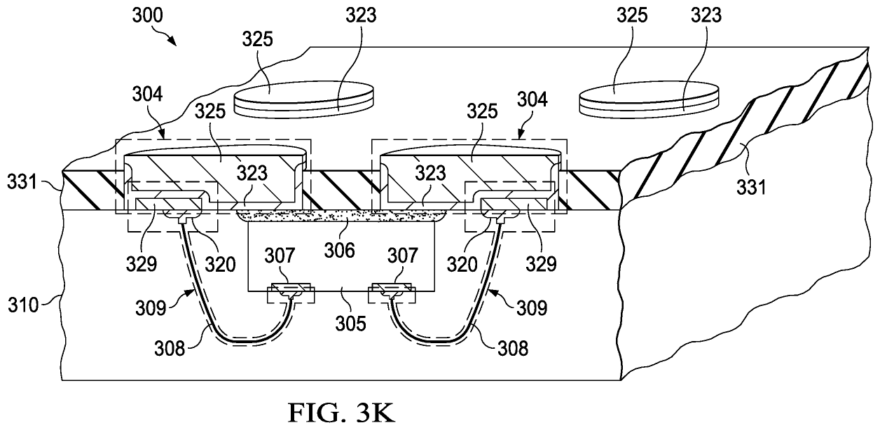

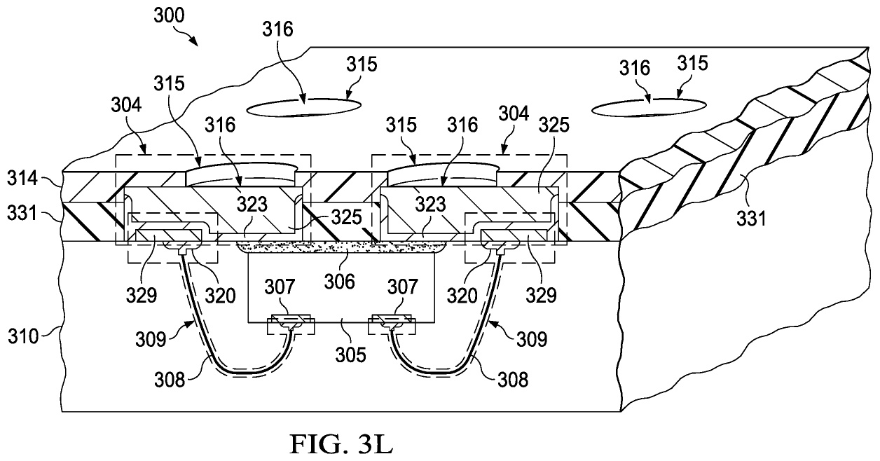

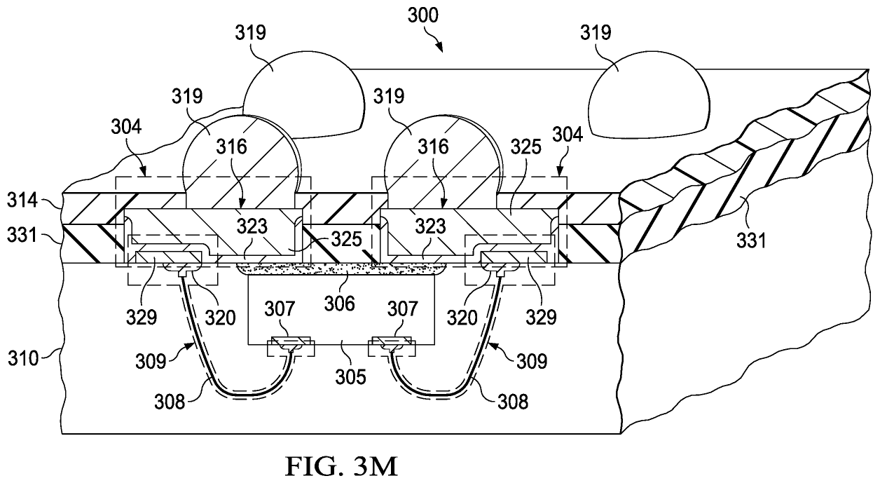

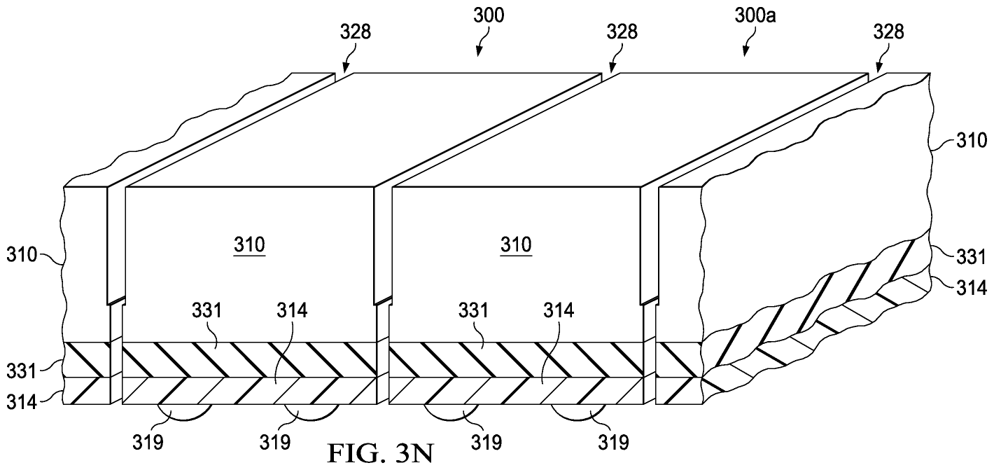

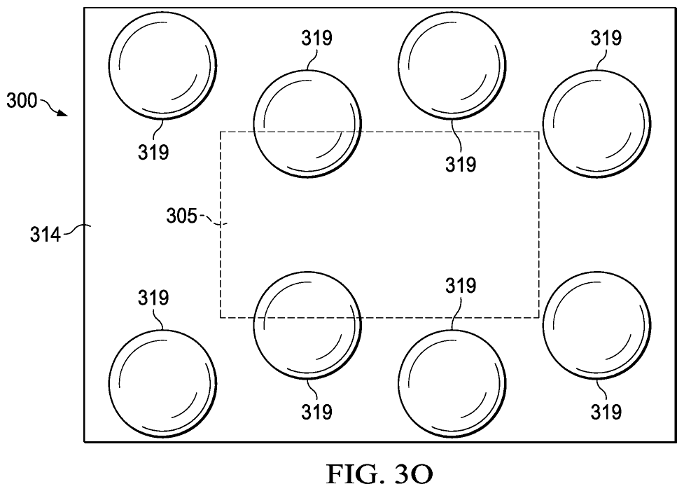

FIG. 3A through FIG. 3O include various views of a microelectronic device having a fan-out fan-in chip scale package, depicted in stages of a further example method of formation. Referring to FIG. 3A, formation of the microelectronic device 300 begins by providing a carrier 301. The carrier 301 includes one or more materials suitable as a substrate for forming wire bond studs. In this example, the carrier 301 may be flexible, to facilitate subsequent removal of the carrier 301. The carrier 301 may include, for example, polycarbonate, phenolic, or acrylic material. The carrier 301 may have a laminated structure, or a fiber-reinforced structure, to provide a desired mechanical strength. Other compositions and structures for the carrier 301 are within the scope of this example. The carrier 301 has an area for the microelectronic device 300, and an adjacent area for an additional microelectronic device 300a. The carrier 301 may have further areas for further microelectronic devices. The carrier 301 may have alignment marks 302 to assist subsequent placement of die on the carrier 301.

An adhesive 303 is disposed on the carrier 301. The adhesive 303 may be implemented as a permanent adhesive or a releasable adhesive. Implementations of the releasable adhesive may include, for example, a thermolabile material, which reduces adhesion of the adhesive 303 upon exposure to a prescribed temperature. Commercially available adhesives with thermolabile materials have a range of prescribed temperatures, from 75° C. to 200° C.

A pad metal layer 326 is disposed on the adhesive 303. The pad metal layer 326 includes metal suitable for forming wire bond studs or ribbon bond wire stitch strips. The pad metal layer 326 also includes metal suitable for forming a seed layer for a subsequent plating process. The pad metal layer 326 may have several sublayers of metal, for example a protective layer of nickel, gold, platinum, or palladium that contacts the adhesive 303, a base layer of copper or copper alloy on the protective layer, and a wire bondable layer of gold or platinum on the base layer. The base layer may be for example, 50 microns to 250 microns thick. In one version of this example, the pad metal layer 326 may be continuous, with no detachment lines to define areas for bump bond pads. In another version, the pad metal layer 326 may have perforations, indents, creases, crimped lines, thinned lines, or such, to define areas for bump bond pads and to assist separation of the pad metal layer 326 in the areas for the bump bond pads from the remaining pad metal layer 326.

A die 305 is attached to the pad metal layer 326 in the area for the microelectronic device 300, and an additional die 305a is attached to the carrier 301 in the area for the additional microelectronic device 300a. The die 305 and the additional die 305a may be manifested as integrated circuits, discrete semiconductor components, electro-optical devices, MEMS devices, or other microelectronic die. The die 305 and the additional die 305a may have terminals 307 providing electrical connections to components in the die 305 and the additional die 305a. The terminals 307 are suitable for wire bonding, and may be manifested as bond pads, or may be manifested as circuit nodes, such as transistor source and drain nodes. The die 305 and the additional die 305a may be substantially similar devices, or may be different devices. The die 305 and the additional die 305a may be attached to the pad metal layer 326 by a die attach material 306, which may include epoxy or other adhesive. The die attach material 306 of this example may be electrically non-conductive, to isolate the die 305 and the additional die 305a from the pad metal layer 326.

Referring to FIG. 3B, wire bond studs 320 of fan-out connections 309 are formed on the pad metal layer 326 using a wire bonding process, in the area for the microelectronic device 300, adjacent to the die 305, and in the area for the additional microelectronic device 300a, adjacent to the additional die 305a. The wire bond studs 320 may be formed by pressing a free air ball of a bond wire onto the carrier 301 with a wire bonding capillary to form a stud, and subsequently severing the bond wire proximate to the stud. The wire bond studs 320 may include primarily copper or gold, and may have some nickel or palladium from a barrier layer around the bond wire. Each fan-out connection 309 may include multiple instances of the wire bond studs 320, as depicted in FIG. 3B. The wire bond studs 320 in each fan-out connection 309 may be formed to abut the other wire bond studs 320 in the same fan-out connection 309, to reduce resistance of the fan-out connection 309. Alternatively, one or more of the fan-out connections 309 may each include a single instance of the wire bond studs 320.

Referring to FIG. 3C, wire bonds 308 of the fan-out connections 309 are formed by a wire bonding process to connect the die 305 and the additional die 305a to the wire bond studs 320. FIG. 3C depicts the wire bonds 308 as formed using round bond wire. Other types of bond wire, such as ribbon bond wire, are within the scope of this example. The wire bonds 308 may include, for example, copper wire, gold wire, or aluminum wire. Copper wire in the wire bonds 308 may optionally have a coating of palladium or nickel to reduce corrosion or oxidation of the copper wire. The wire bonds 308 may be formed with ball bonds on the terminals 307 and stitch bonds on the wire bond studs 320, as depicted in FIG. 3C. Alternatively, the wire bonds 308 may be formed with stitch bonds on the terminals 307 and ball bonds on the wire bond studs 320. Each fan-out connection 309 may include a single instance of the wire bonds 308, as depicted in FIG. 3C. Alternatively, one or more of the fan-out connections 309 may include two or more instances of the wire bonds 308, to increase a current capacity of the fan-out connections 309.

Referring to FIG. 3D, an encapsulation material 310 is formed over the die 305, the additional die 305a, the wire bonds 308, and the wire bond studs 320. The encapsulation material 310 contacts the die 305 and the additional die 305a. The encapsulation material 310 may include epoxy or other material suitable for protecting the die 305, the additional die 305a, the wire bonds 308, and the wire bond studs 320 from moisture and contamination. In this example, the encapsulation material 310 may be formed by using a press mold 311 having singulation fins 327, which produce singulation trenches 328 in the encapsulation material 310 around a perimeter of the microelectronic device 300. The singulation trenches 328 may facilitate subsequent singulation of the microelectronic device 300 from the additional microelectronic devices 300a. The encapsulation material 310 extends to the pad metal layer 326 adjacent to the die 305 and adjacent to the wire bond studs 320.

Referring to FIG. 3E, the carrier 301 and the adhesive 303 are removed from the microelectronic device 300 and the additional microelectronic device 300a. Portions of the pad metal layer 326 contacting the wire bond studs 320 remain attached to the wire bond studs 320, providing metal pads 329, shown in FIG. 3F, of the fan-out connections 309. Referring back to FIG. 3E, portions of the pad metal layer 326 outside of areas for the metal pads 329 remain attached to the adhesive 303, and are removed from the microelectronic device 300 with the carrier 301 and the adhesive 303. The adhesive 303 may be weakened to facilitate removal of the carrier 301, while maintaining attachment to the portions of the pad metal layer 326 outside of areas for the metal pads 329. In this example, the adhesive 303 may be weakened by heating the adhesive 303 with heated rollers 330.

FIG. 3F depicts the microelectronic device 300 and the additional microelectronic device 300a after removal of the carrier 301 and the adhesive 303 of FIG. 3E. The metal pads 329 of the fan-out connections 309 are exposed at a surface of the encapsulation material 310.

FIG. 3G depicts the microelectronic device 300 in an inverted orientation with respect to FIG. 3F. In the instant example, a combination of the wire bonds 308, the wire bond studs 320, and the metal pads 329 provide the fan-out connections 309. The fan-out connections 309 are formed without using a photolithographic process, which may advantageously reduce a fabrication cost and a fabrication complexity of the microelectronic device 300.

A permanent dielectric layer 331 is formed on the encapsulation material 310, exposing the metal pads 329 and adjacent areas of the encapsulation material 310, in areas for subsequently-formed fan-in/out traces. The permanent dielectric layer 331 may include, for example, epoxy, polyimide, silicone polymer, or inorganic dielectric material such as ceramic. The permanent dielectric layer 331 may be formed using a tape transfer process, a screen printing process, or an additive process, such as a material jetting process or a material extrusion process.

Referring to FIG. 3H, a plating seed layer 323 is formed on the permanent dielectric layer 331, extending onto the metal pads 329. The plating seed layer 323 is electrically conductive, and includes metals or other electrically conductive material suitable for a plating process. The plating seed layer 323 may include, for example, copper or copper alloy, nickel, platinum, palladium, or gold. The plating seed layer 323 may be, for example, 500 nanometers to 10 microns thick, and may be formed by a sputter process, an evaporation process, or a metal plasma spray process.

Referring to FIG. 3I, a plating mask 324 is formed on the plating seed layer 323. The plating mask 324 exposes the plating seed layer 323 in the areas for fan-in/out traces 304. The plating mask 324 may include polymer material, for example, novolac resin, which may be removed by organic solvents. The plating mask 324 may be formed, for example, by a tape transfer process, or by an additive process, such as a material jetting process. The plating mask 324 may have a thickness of 1 microns to 10 microns, for example.

Referring to FIG. 3J, plated leads 325 of fan-in/out traces 304 are formed by an electroplating process on the plating seed layer 323 where exposed by the plating mask 324. The plated leads 325 may extend above the plating seed layer 323, as depicted in FIG. 3J. The plated leads 325 may include a base layer of copper that contacts the plating seed layer 323, and may include a barrier layer on the base layer. The base layer may include copper or a copper alloy, and may have a thickness of 5 microns to 100 microns. The barrier layer may include nickel, palladium, cobalt, titanium, or molybdenum, to reduce formation of intermetallic compounds between copper in the base layer and tin in subsequently formed solder bumps on the plated leads 325.

Referring to FIG. 3K, the plating mask 324 of FIG. 3J is removed. The plating mask 324 may be removed by a wet process using organic solvents, or by a dry process using oxygen radicals. Subsequently, the plating seed layer 323 is removed where exposed by the plated leads 325. The plating seed layer 323 may be removed by a wet etch process. Removal of the plating seed layer 323 leaves the plated leads 325 in place, and leaves the plating seed layer 323 in place under the plated leads 325. The plating seed layer 323 under the plated leads 325, combined with the plated leads 325, provides the fan-in/out traces 304. At least a portion of the fan-in/out traces 304 extend over the die 305.

Referring to FIG. 3L, a solder mask 314 is formed on the permanent dielectric layer 331 and the fan-in/out traces 304. The solder mask 314 has solder bump apertures 315 which expose areas of the fan-in/out traces 304 for bump bond pads 316. The solder mask 314 may include a polymer material. The solder mask 314 may be formed, for example, by a screen printing process, an additive process, or a tape transfer process. A portion of the fan-in/out traces 304 extend partway under the die 305. The bump bond pads 316 in this portion of the fan-in/out traces 304 are located at least partially under the die 305.

Referring to FIG. 3M, an electrically conductive connection material 319 is formed on the bump bond pads 316. The electrically conductive connection material 319 may be implemented as solder bumps 319, which may include tin and other metals, such as silver, copper, bismuth, or indium, to provide a desired melting temperature, resistance, and reliability. The solder bumps 319 may be formed by placing preformed solder balls onto the bump bond pads 316, disposing solder paste onto the bump bond pads 316, or providing melted solder on the bump bond pads 316. Formation of the solder bumps 319 may include a solder reflow process to provide a desired composition of the solder bumps 319 and to improve contact between the solder bumps 319 and the bump bond pads 316.

Referring to FIG. 3N, the microelectronic device 300 is singulated by severing the encapsulation material 310, the permanent dielectric layer 331, and the solder mask 314 under the singulation trenches 328 around a lateral perimeter of the microelectronic device 300. The microelectronic device 300 may be singulated by stressing the encapsulation material 310 under the singulation trenches 328, for example by using a breaking dome. Singulating the microelectronic device 300 may be facilitated by the absence of metal under the singulation trenches 328.

FIG. 3O is a bottom view of the microelectronic device 300. A fan-in portion of the solder bumps 319 overlap at least partway over the die 305. A fan-out portion of the solder bumps 319 may be located adjacent to the die 305 without overlapping partway over the die 305. Having the solder bumps 319 located so as to both overlap at least partway over the die 305 and adjacent to the die 305 without overlapping partway over the die 305 may advantageously reduce an area of the microelectronic device 300 while maintaining isolation between the solder bumps 319.

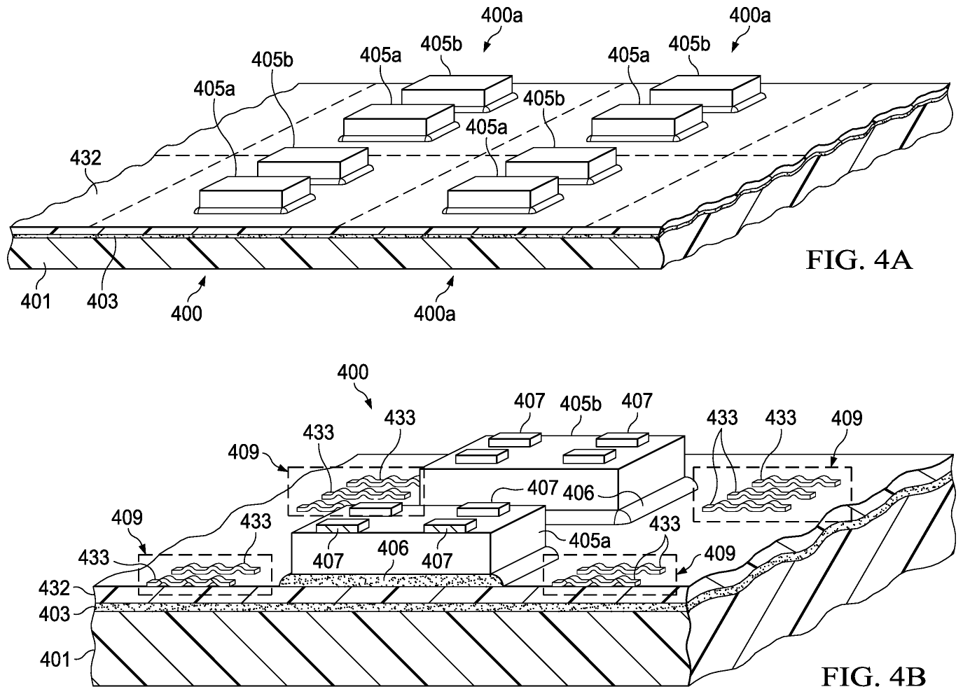

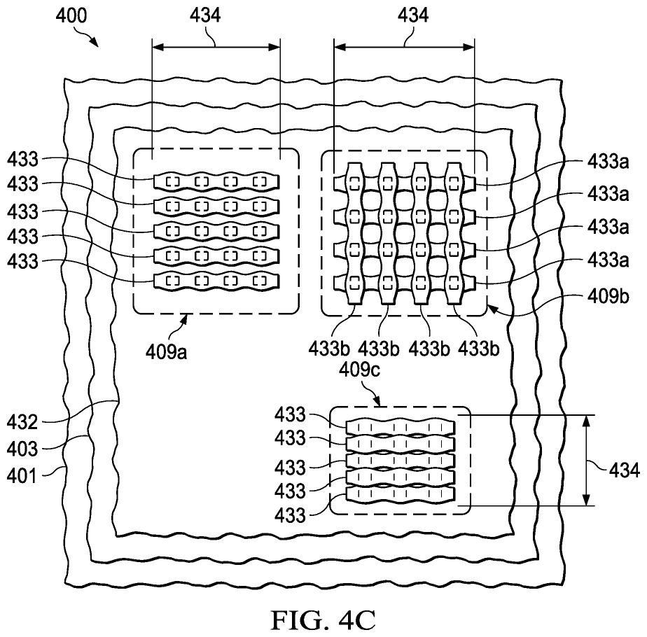

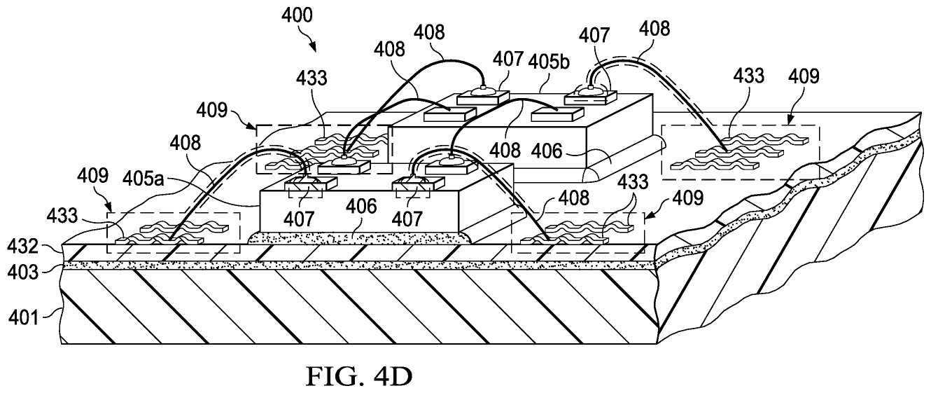

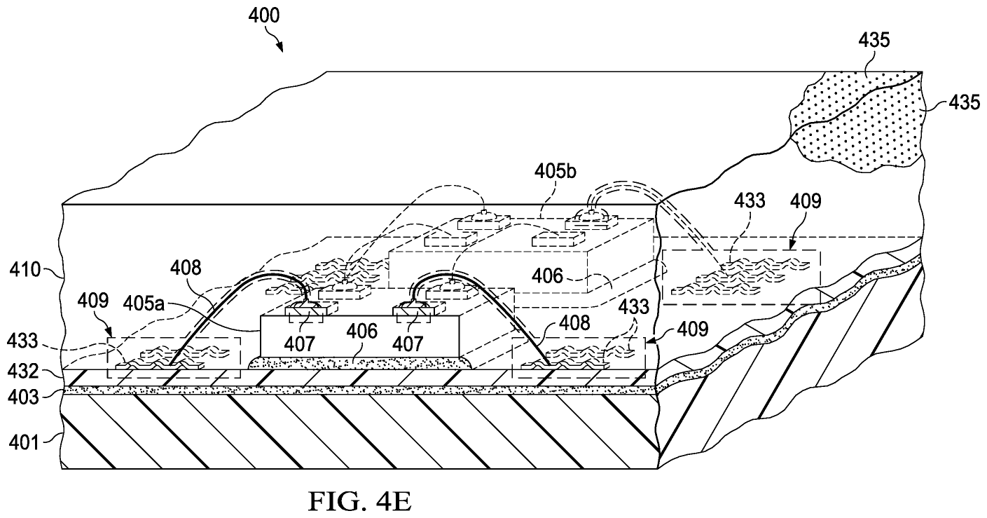

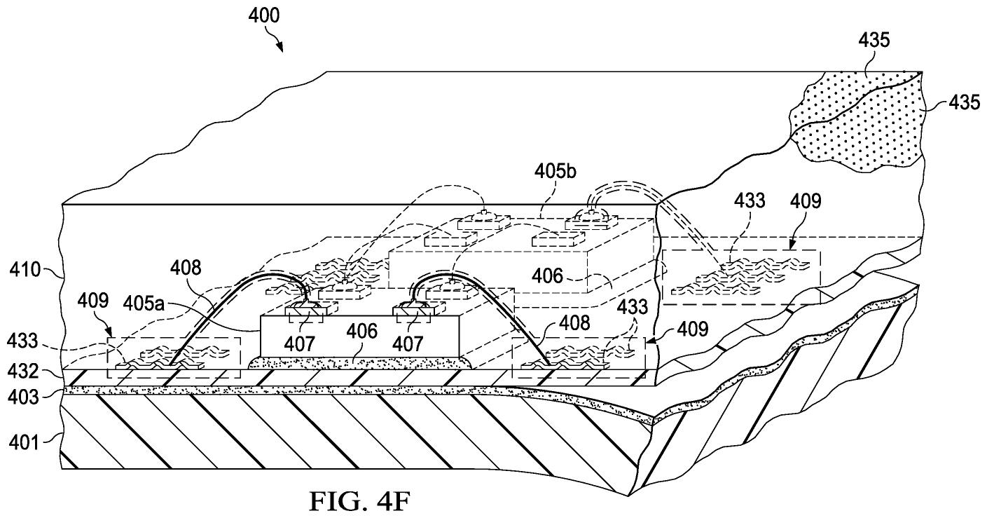

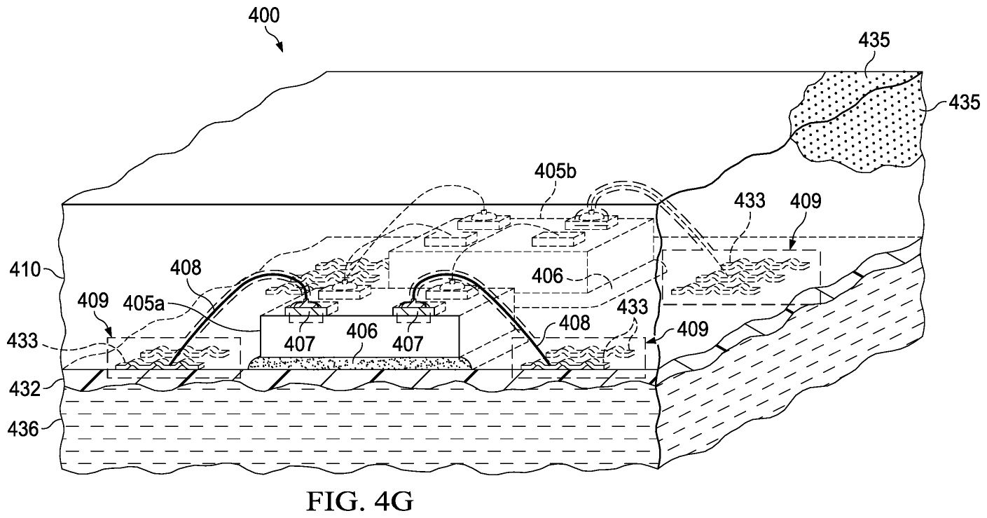

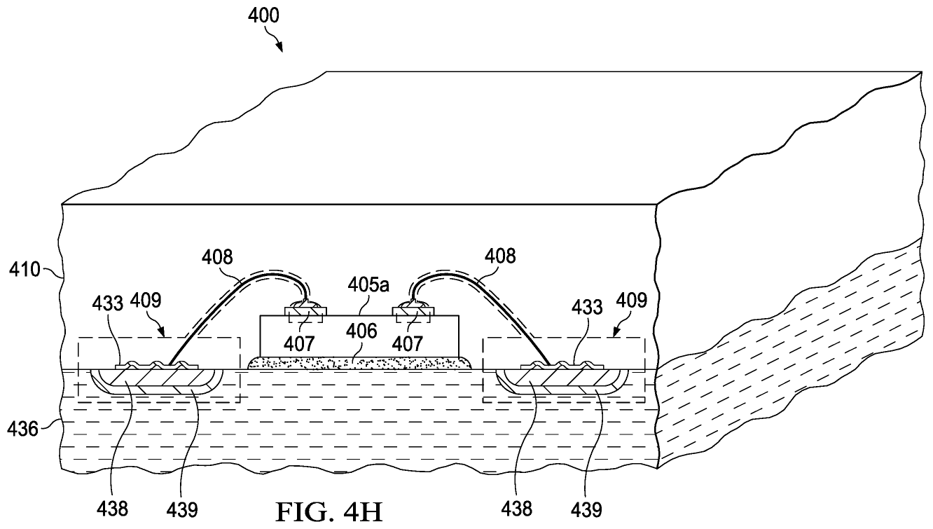

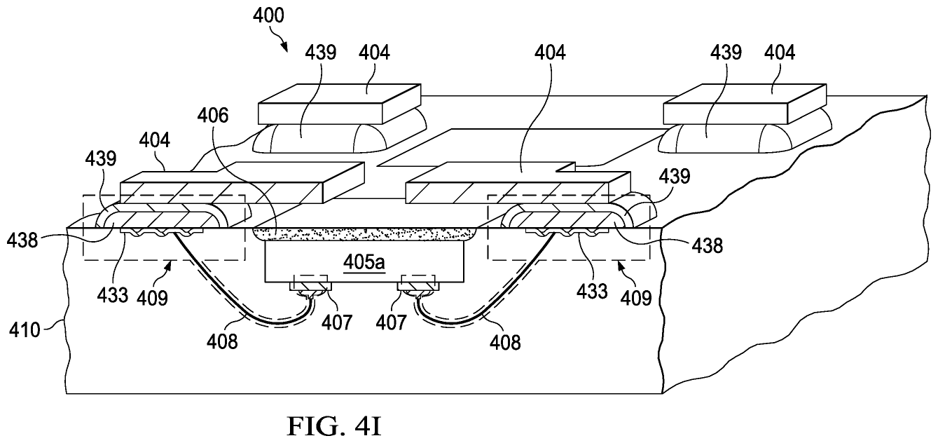

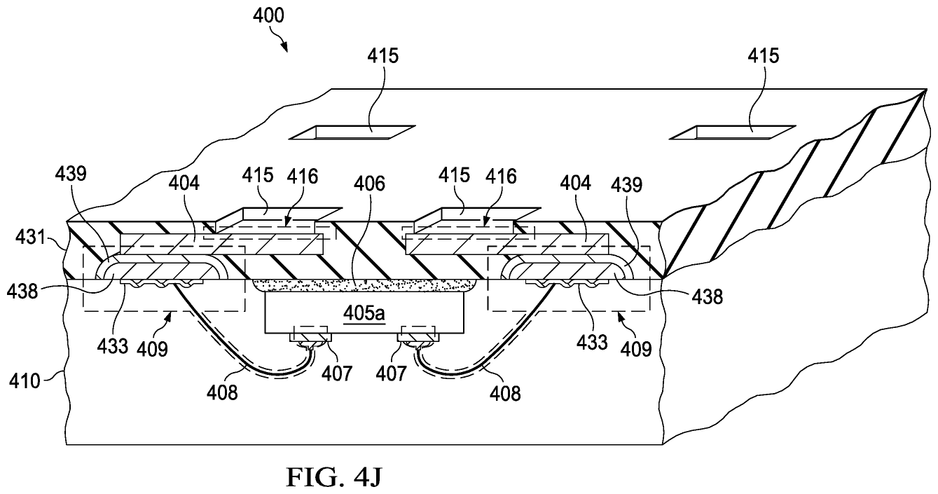

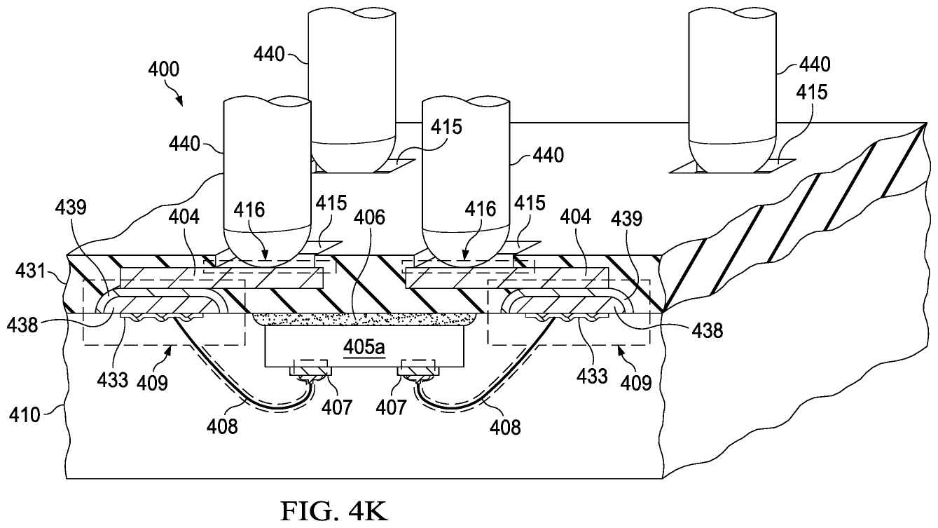

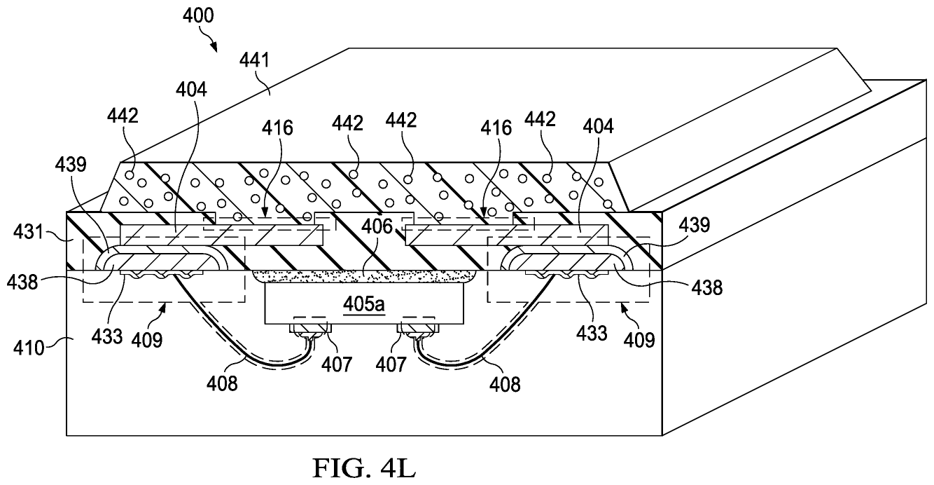

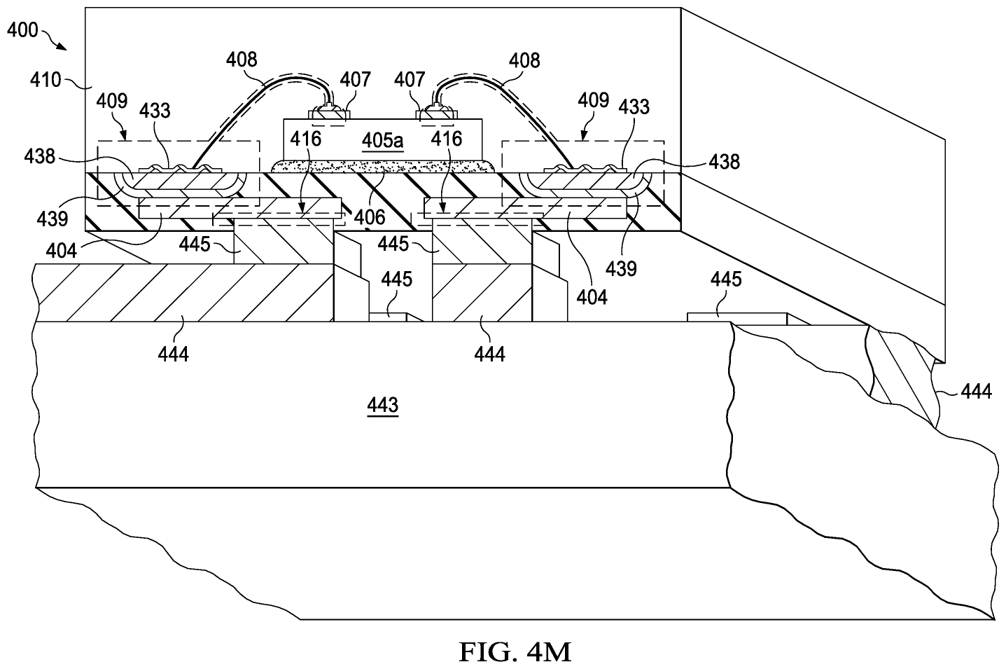

FIG. 4A through FIG. 4M include various views of a microelectronic device having a fan-out fan-in chip scale package, depicted in stages of a further example method of formation. Referring to FIG. 4A, formation of the microelectronic device 400 begins by providing a carrier 401. In this example, the carrier 401 may be flexible, to facilitate subsequent removal of the carrier 401. The carrier 401 may include, for example, polycarbonate, phenolic, or acrylic material. The carrier 401 may have a laminated structure, or a fiber-reinforced structure, to provide a desired mechanical strength. Other compositions and structures for the carrier 401 are within the scope of this example. The carrier 401 has an area for the microelectronic device 400, and areas for additional microelectronic devices 400a. The carrier 401 may have alignment marks, not shown in FIG. 4A, to assist subsequent placement of die on the carrier 401.

A releasable adhesive 403 is disposed on the carrier 401. A sacrificial layer 432 is disposed on the releasable adhesive 403. The sacrificial layer 432 includes one or more materials having a hardness suitable for forming ribbon stitch bonds or wire bond studs. The sacrificial layer 432 includes materials which can be removed from the microelectronic device 400 without degrading the microelectronic device 400, for example by a wet etch process. The sacrificial layer 432 may include, for example, aluminum oxide, aluminum nitride, polycrystalline silicon, hydrogen-rich silicon nitride, or phosphosilicate glass (PSG). The sacrificial layer 432 may be 1 micron to 10 microns thick, to facilitate removal from the microelectronic device 400. The releasable adhesive 403 may include, for example, a microsuction tape which has microscopic pores on a face of the releasable adhesive 403 contacting the sacrificial layer 432. The microsuction tape adheres to the sacrificial layer 432 without use of conventional adhesives. The microsuction tape may be permanently affixed to the carrier 401, for example by a permanent adhesive. The microsuction tape may be separated from the sacrificial layer 432 by peeling the carrier 401 from the sacrificial layer 432. Alternatively, the releasable adhesive 403 may include a non-permanent adhesive material, a thermolabile material, or a Photolabile material.

In this example, a first die 405a and a second die 405b are attached to the sacrificial layer 432 in an area for the microelectronic device 400. Additional instances of the first die 405a and the second die 405b may be attached to the sacrificial layer 432 in separate areas for additional microelectronic devices 400a, as depicted in FIG. 4A. Either of the first die 405a and the second die 405b may be manifested as an integrated circuit, a discrete semiconductor component, an electro-optical device, a MEMS device, or other microelectronic die. The first die 405a and the second die 405b may be separate types of devices.

FIG. 4B shows the microelectronic device 400 in more detail. In this example, the first die 405a and the second die 405b may be attached to the sacrificial layer 432 by a die attach layer 406, or by another material or method. In this example, the die attach layer 406 may be electrically non-conductive, to isolate the first die 405a and the second die 405b. The die attach layer 406 may be implemented as an adhesive such as epoxy, to provide a desired level of electrical isolation. The first die 405a and the second die 405b may have terminals 407 for electrical connections to components in the first die 405a and the second die 405b. The terminals 407 may be manifested as bond pads, or circuit nodes. The terminals 407 may include materials suitable for wire bonding.

Ribbon stitch bond strips 433 are formed of ribbon wire on the sacrificial layer 432 adjacent to the first die 405a and the second die 405b, using a ribbon bond wire bonding process. The ribbon stitch bond strips 433 provide initial portions of fan-out connections 409 of the microelectronic device 400. Multiple ribbon stitch bond strips 433 may be formed in each of the fan-out connections 409, to provide lower resistance between the fan-out connections 409 and subsequently-formed fan-in/out traces 404, shown in FIG. 4J. Referring back to FIG. 4B, the ribbon stitch bond strips 433 in each fan-out connection 409 may be formed to contact each other, or may be separated by a few microns. The sacrificial layer 432 may facilitate forming the ribbon stitch bond strips 433 by providing a suitable surface for ribbon stitch bonding, to which the ribbon wire adheres.

FIG. 4C depicts example configurations of the ribbon stitch bond strips 433 in the fan-out connections 409 of FIG. 4B. A first fan-out connection 409a may have a parallel non-contacting configuration, with ribbon stitch bond strips 433 arranged in parallel. Adjacent ribbon stitch bond strips 433 in the first fan-out connection 409a may be separated by a lateral space that is sufficiently narrow, so that subsequently-plated metal on the adjacent ribbon stitch bond strips 433 in the first fan-out connection 409a merges together to form a metal pad that is continuous across all the ribbon stitch bond strips 433 in the first fan-out connection 409a. The first fan-out connection 409a may have a minimum lateral dimension 434 of 50 microns to 300 microns. The term “lateral” refers to a direction parallel to a face of the sacrificial layer 432 on which the ribbon stitch bond strips 433 are formed. The minimum lateral dimension 434 may be selected provide a sufficient area for subsequent attachment of the fan-in/out traces 404, shown in FIG. 4J.

Referring back to FIG. 4C, a second fan-out connection 409b may have a crossed parallel configuration, with first ribbon stitch bond strips 433a formed parallel to each other, and second ribbon stitch bond strips 433b formed parallel to each other and perpendicular to the first ribbon stitch bond strips 433a. Each of the first ribbon stitch bond strips 433a may contact each of the second ribbon stitch bond strips 433b. The first ribbon stitch bond strips 433a and the second ribbon stitch bond strips 433b may be formed with open spaces between the first ribbon stitch bond strips 433a and the second ribbon stitch bond strips 433b, as indicated in FIG. 4C. Adjacent instances of the first ribbon stitch bond strips 433a and the second ribbon stitch bond strips 433b may be formed sufficiently close to each other so that subsequently-plated metal on the adjacent first ribbon stitch bond strips 433a and the adjacent second ribbon stitch bond strips 433b in the second fan-out connection 409b merges together to form a metal pad that is continuous across all the first ribbon stitch bond strips 433a and the second ribbon stitch bond strips 433b in the first ribbon stitch bond strips 433a and the second ribbon stitch bond strips 433b. The second fan-out connection 409b may have a minimum lateral dimension 434 of 50 microns to 300 microns, to provide a sufficient area for subsequent attachment of the fan-in/out traces 404.

A third fan-out connection 409c may have a parallel contacting configuration, with ribbon stitch bond strips 433 arranged in parallel. Adjacent ribbon stitch bond strips 433 in the third fan-out connection 409c may be formed so as to contact each other, as indicated in FIG. 4C. The third fan-out connection 409c may have a minimum lateral dimension 434 of 50 microns to 300 microns, to provide a sufficient area for subsequent attachment of the fan-in/out traces 404.

Referring to FIG. 4D, wire bonds 408 are formed by a wire bonding process to connect the first die 405a and the second die 405b to the ribbon stitch bond strips 433. FIG. 4D depicts the wire bonds 408 as formed using round bond wire. Other types of bond wire, such as ribbon bond wire, are within the scope of this example. The wire bonds 408 may include, for example, copper wire, coated copper wire, gold wire, or aluminum wire. The wire bonds 408 may be formed with ball bonds on the terminals 407 of the first die 405a and the second die 405b, and stitch bonds on the ribbon stitch bond strips 433, as depicted in FIG. 4D. Alternatively, the wire bonds 408 may be formed with ball bonds on the ribbon stitch bond strips 433 and stitch bonds on the terminals 407 of the first die 405a and the second die 405b. The wire bonds 408 may also directly connect the first die 405a and the second die 405b, as depicted in FIG. 4D. The wire bonds 408 connecting the first die 405a and the second die 405b to the ribbon stitch bond strips 433 are parts of the fan-out connections 409.

Referring to FIG. 4E, an encapsulation material 410 is formed over the first die 405a and the second die 405b, the wire bonds 408, and the ribbon stitch bond strips 433. The encapsulation material 410 contact the first die 405a and the second die 405b. The encapsulation material 410 may include epoxy or other material suitable for protecting the first die 405a and the second die 405b, the wire bonds 408, and the ribbon stitch bond strips 433 from moisture and contamination. Fill particles 435 may be distributed in the encapsulation material 410. In one version of this example, the fill particles 435 may have a thermal expansion coefficient between an average thermal expansion coefficient of the first die 405a and the second die 405b, and a thermal expansion coefficient of a circuit board on which the microelectronic device 400 will be mounted, which may provide improved mechanical reliability, compared to a similar device with no fill particles 435 in the encapsulation material 410. In another version of this example, the fill particles 435 may have a thermal conductivity higher than a thermal conductivity of the encapsulation material 410, which may provide a reduced operating temperature for the first die 405a and the second die 405b, and thus improved reliability, compared to a similar device with no fill particles 435 in the encapsulation material 410.

Referring to FIG. 4F, the carrier 401 and the releasable adhesive 403 are removed from the microelectronic device 400, leaving the sacrificial layer 432 attached to the microelectronic device 400. In versions of this example in which the releasable adhesive 403 is implemented having the microsuction tape, the carrier 401 and the releasable adhesive 403 may be removed by a peeling process, as indicated in FIG. 4F. In versions of this example in which the releasable adhesive 403 is implemented with a photolabile material or thermolabile material, the releasable adhesive 403 may be weakened, for example by exposure to UV radiation or by heating, as appropriate, to facilitate removal of the carrier 401.

Referring to FIG. 4G, the sacrificial layer 432 is removed from the microelectronic device 400, exposing the ribbon stitch bond strips 433. The sacrificial layer 432 may be removed using a wet etch bath 436 which etches the sacrificial layer 432 without significantly degrading the microelectronic device 400. For example, the wet etch bath 436 may include an aqueous solution of potassium hydroxide, tetramethylammonium hydroxide, or choline hydroxide, which may remove aluminum oxide, aluminum nitride, polycrystalline silicon, hydrogen-rich silicon nitride, or PSG in the sacrificial layer 432 without significantly degrading copper or gold in the ribbon stitch bond strips 433.

Referring to FIG. 4H, a plating process using a plating bath 437 forms one or more plated metal layers of the fan-out connections 409 on the ribbon stitch bond strips 433 where exposed by the encapsulation material 410. The one or more plated metal layers may include a base layer 438 on the ribbon stitch bond strips 433, and a barrier layer 439 on the base layer 438. The chemistry of the plating bath 437 may be changed to provide desired compositions of the one or more plated metal layers. The plating process may be implemented as an autocatalytic electroless process or an immersion process, for example. An autocatalytic electroless process may be continued as long as needed to provide a desired thickness of the metal layer. An immersion process is substantially self-limiting, producing a metal layer that is a few nanometers thick. The base layer 438 may include a metal with a high electrical conductivity, such as copper, and may be formed to be 50 microns to 150 microns thick, to provide a low resistance for the fan-out connections 409. The barrier layer 439 may include one or more metals that provide a surface appropriate for subsequently attaching fan-in/out traces 404, shown in FIG. 4J. Referring back to FIG. 4H, the barrier layer 439 may include, for example, nickel, palladium, or platinum. The barrier layer 439 may be formed to be 10 microns to 40 microns thick, for example. The base layer 438 and the barrier layer 439 may be characterized by a conformal configuration on the ribbon stitch bond strips 433, in which the base layer 438 and the barrier layer 439 conform to contours of the ribbon stitch bond strips 433, resulting from the plating process. The base layer 438 and the barrier layer 439 are parts of the fan-out connections 409, along with the ribbon stitch bond strips 433 and the wire bonds 408, in this example. All the elements of the fan-out connections 409, that is, the ribbon stitch bond strips 433, the wire bonds 408, the base layer 438, and the barrier layer 439, are formed without using a photolithographic process, which may advantageously reduce fabrication cost and fabrication complexity of the microelectronic device 400.

Referring to FIG. 4I, fan-in/out traces 404 are attached to the fan-out connections 409. In this example, the fan-in/out traces 404 may be implemented as preformed leads, and may be attached to the fan-out connections 409 by microwelding. The fan-in/out traces 404 may include copper, clad with nickel or stainless steel, for example. The fan-in/out traces 404 may be by a punch process. Other implementations of the fan-in/out traces 404, and other methods of attaching the fan-in/out traces 404 to the fan-out connections 409, are within the scope of this example. A portion of the fan-in/out traces 404 extend partway over the first die 405a. A portion of the fan-in/out traces 404 extend partway over the second die 405b, which is obscured in FIG. 4I by the encapsulation material 410.

Referring to FIG. 4J, a permanent dielectric layer 431 is formed on the encapsulation material 410, surrounding the fan-in/out traces 404. The permanent dielectric layer 431 has solder bump apertures 415 which expose areas of the fan-in/out traces 404 for bump bond pads 416. The permanent dielectric layer 431 may advantageously provide mechanical support for the fan-in/out traces 404. The permanent dielectric layer 431 may include, one or more dielectric materials, such as epoxy, polyimide, silicone polymer, or inorganic dielectric material such as ceramic. The permanent dielectric layer 431 may be formed in two or more sublayers, to facilitate surrounding the fan-in/out traces 404. Sublayers of the permanent dielectric layer 431 may variously be formed by a screen printing process, or an additive process, such as a material jetting process or a material extrusion process. The configuration of the fan-in/out traces 404, wherein a portion of the fan-in/out traces 404 extend partway over the first die 405a and the second die 405b, and another portion of the fan-in/out traces 404 is located adjacent to the first die 405a and the second die 405b, may advantageously enable a more space-efficient layout of the bump bond pads 416, compared to a fan-out-only layout, thus advantageously enabling a smaller area for the microelectronic device 400.

Referring to FIG. 4K, the microelectronic device 400 may be electrically tested. Testing the microelectronic device 400 may be performed by contacting test probes 440 to the bump bond pads 416, and applying test signals and biases to the microelectronic device 400 through the test probes 440. A device identification mark, not shown in FIG. 4K, may be formed on the encapsulation material 410, to indicate a device type for the microelectronic device 400, and optionally to indicate results of the electrical testing of the microelectronic device 400.

Referring to FIG. 4L, in this example, a solder anisotropic conductive film 441 is applied to the microelectronic device 400, contacting the bump bond pads 416. The solder anisotropic conductive film 441 may include solder particles 442 in an adhesive binder. The solder anisotropic conductive film 441 may be applied in a tape format, or may be applied in a paste format. The solder anisotropic conductive film 441 is commercially available from various suppliers.

Referring to FIG. 4M, the microelectronic device 400 is positioned on a circuit substrate 443 having traces 444. The circuit substrate 443 may be implemented as a printed circuit board, a chip carrier, for example. The microelectronic device 400 is positioned on the circuit substrate 443 so that the bump bond pads 416 are aligned with the traces 444 and the solder anisotropic conductive film 441 of FIG. 4L contacts the traces 444. The solder anisotropic conductive film 441 is heated, causing the solder particles 442 of FIG. 4L to melt and collect in solder connections 445 that connect the bump bond pads 416 with the traces 444. Remaining material of the solder anisotropic conductive film 441, including the adhesive binder, is not shown in FIG. 4M to more clearly show the solder connections 445.

Various features of the examples disclosed herein may be combined in other manifestations of example microelectronic devices. For example, multiple die may be included in the example microelectronic devices disclosed in reference to FIG. 1A through FIG. 1J, FIG. 2A through FIG. 2L, and FIG. 3A through FIG. 3O, similar to the example disclosed in reference to FIG. 4A through FIG. 4M. Encapsulation material may be formed on the example microelectronic devices disclosed in the examples herein by any of the methods disclosed in reference to FIG. 1A through FIG. 1J, FIG. 2A through FIG. 2L, FIG. 3A through FIG. 3O, and FIG. 4A through FIG. 4M. Singulation may be performed by any of the methods disclosed in reference to FIG. 1A through FIG. 1J, FIG. 2A through FIG. 2L, and FIG. 3A through FIG. 3O. Testing of the example microelectronic devices may be performed at any stage of formation, and is not limited to the method disclosed in reference to FIG. 4A through FIG. 4M. Device identification marks may be formed on the microelectronic devices at any stage of formation, and is not limited to specific steps disclosed in reference to FIG. 1A through FIG. 1J, FIG. 2A through FIG. 2L, FIG. 3A through FIG. 3O, and FIG. 4A through FIG. 4M. Elements of the example microelectronic devices described herein, such as the fan-out connections, the wire bonds, the fan-in/out traces, and the encapsulation material, may be formed according to methods disclosed with regard to analogous elements in the following commonly assigned U.S. patent applications: U.S. patent application Ser. No. 12/______, Attorney Docket Number TI-78741, filed concurrently with this application, U.S. patent application Ser. No. 12/______, Attorney Docket Number TI-78743, filed concurrently with this application, and U.S. patent application Ser. No. 12/______, Attorney Docket Number TI-78745, filed concurrently with this application. These commonly assigned U.S. patent applications are incorporated herein by reference but are not admitted to be prior art with respect to the present invention by their mention in this section.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a first die;
fan-out connections tending from the die, the fan-out connections including wire bonds, wherein the fan-out connections are free of photolithographically-defined structures;
fan-in/out traces connected to the fan-out connections, the fan-in/out traces having bump bond pads, wherein the first die and a portion of the bump bond pads partially overlap each other;
an encapsulation material surrounding the wire bonds, at least partially surrounding the first die and contacting the first die, wherein the fan-in/out traces are located outside of the encapsulation material; and
an electrically conductive connection material disposed on the bump bond pads, wherein the electrically conductive connection material is outside of the encapsulation material.

2. The microelectronic device of claim 1, wherein each of the fan-out connections includes a plurality of wire stud bonds.

3. The microelectronic device of claim 2, wherein each of the fan-out connections includes a metal pad contacting the wire stud bonds.

4. The microelectronic device of claim 1, wherein the fan-out connections include a plurality of ribbon stitch bond strips.

5. The microelectronic device of claim 1, wherein the fan-out connections include plated metal, wherein the plated metal conforms to contours of electrically conductive elements of the fan-out connections contacting the plated metal.

6. The microelectronic device of claim 1, wherein the fan-in/out traces include preformed metal pads.

7. The microelectronic device of claim 1, wherein the fan-in/out traces include plated metal and a seed layer.

8. The microelectronic device of claim 1, further including a second die, wherein the second die is at least partially surrounded and contacted by the encapsulation material.

9. The microelectronic device of claim 1, further including fill particles distributed in the encapsulation material, wherein the fill particles have a thermal expansion coefficient higher than a thermal expansion coefficient of the first die.

10. The microelectronic device of claim 1, wherein the microelectronic device is free of electrically conductive leads extending to lateral surfaces of the encapsulation material, the lateral surfaces being perpendicular to a surface of the encapsulation material contacting the bump bond pads.

11. A method of forming a microelectronic device, comprising:
acquiring a carrier;
disposing a first die on the carrier;
forming at least portions of fan-out connections on the carrier, by a method free of a photolithographic process, wherein forming the fan-out connections includes forming wire bonds that connect to the first die;
forming an encapsulation material over the first die and the wire bonds, wherein the encapsulation material contacts the at least portions of the fan-out connections;
removing the carrier, wherein the at least portions of the fan-out connections are exposed at a surface of the encapsulation material; and
forming fan-in/out traces that contact the fan-out connections, the fan-in/out traces having bump bond pads, wherein the first die and a portion of the bump bond pads partially overlap each other.

12. The method of claim 11, wherein a releasable adhesive is disposed on the carrier prior to disposing the first die on the carrier.

13. The method of claim 12, wherein the releasable adhesive includes a photolabile material.

14. The method of claim 12, wherein the releasable adhesive includes a thermolabile material.

15. The method of claim 11, wherein forming the at least portions of the fan-out connections includes forming a plurality of wire stud bonds on the carrier.

16. The method of claim 11, wherein preformed metal pads are disposed on the carrier prior to forming the wire bonds, the preformed metal pads providing at least portions of the fan-in/out traces.

17. The method of claim 11, wherein:
a pad metal layer is disposed on the carrier prior to forming the wire bonds; and
removing the carrier includes removing a portion of the pad metal layer, wherein portions of the pad metal layer contacting the at least portions of the fan-out connections remain attached to the at least portions of the fan-out connections.

18. The method of claim 11, further including plating metal on the at least portions of the fan-out connections after removing the carrier.

19. The method of claim 11, further including disposing a solder on the bump bond pads.

20. The method of claim 11, further including disposing a second die on the carrier prior to forming the encapsulation material.
